(19) United States
(12) Patent Application Publication
(10) Pub. No.: US 2026/0282637 A1
(43) Pub. Date: Sep. 17, 2026

(54) DISPLAY COMPRISING COLOR CONVERSION LAYER

(71) Applicant: SAMSUNG ELECTRONICS CO., LTD., Suwon-si (KR)

(72) Inventors: ILJU MUN, Suwon-si (KR); Seongyong KIM, Suwon-si (KR); Hojin KIM, Suwon-si (KR); Keon KUK, Suwon-si (KR); Yeseul PARK, Suwon-si (KR); Jinwoo JUNG, Suwon-si (KR)

(73) Assignee: SAMSUNG ELECTRONICS CO., LTD., Suwon-si (KR)

(21) Appl. No.: 19/683,175

(22) Filed: May 20, 2026

Related U.S. Application Data
(63) Continuation of application No. PCT/KR2024/016438, filed on Oct. 25, 2024.

(30) Foreign Application Priority Data
Nov. 20, 2023 (KR) 10-2023-0161517
Jan. 11, 2024 (KR) 10-2024-0004714

(51) Int. Cl. H10H 29/851; H10H 29/80; H10H 29/853; H10H 29/854

(52) U.S. Cl. CPC H10H 29/8514; H10H 29/842; H10H 29/853; H10H 29/854

(57) ABSTRACT

A display includes a light source panel and a color conversion panel facing the light source panel. The color conversion panel includes: a front substrate; a color conversion layer on the front substrate; a barrier wall on the front substrate and separating each of a plurality of sub-pixels of the display; an organic resin layer on a side surface of the barrier wall, the organic resin layer separates the plurality of sub-pixels at an outermost position of the front substrate, and the organic resin layer is between a side surface of the barrier wall and a side surface of the front substrate; and a thin film encapsulation layer on the organic resin layer.

### CROSS-REFERENCE TO RELATED APPLICATIONS

This application is a continuation of International Application No. PCT/KR2024/016438, filed on October 25, 2024, which is based on and claims priority to Korean Patent Application No. 10-2023-0161517, filed on November 20, 2023, in the Korean Intellectual Property Office, and Korean Patent Application No. 10-2024-0004714, filed on January 11, 2024, in the Korean Ministry of Intellectual Property, the disclosures of which are incorporated by reference herein in their entireties.

### BACKGROUND

### 1. Field

The disclosure relates to a display including a color conversion layer.

### 2. Description of Related Art

An electronic device may provide various functions based on various types of applications. In the process of providing the various functions, the electronic device may output to a screen corresponding to each of the functions. A user may want to use a wider screen when using the various functions described above.

### SUMMARY

According to an aspect of the disclosure, a display includes a light source panel and a color conversion panel facing the light source panel. The color conversion panel includes: a front substrate; a color conversion layer on the front substrate; a barrier wall on the front substrate and separating each of a plurality of sub-pixels of the display; an organic resin layer on a side surface of the barrier wall. The organic resin layer separates the plurality of sub-pixels at an outermost position of the front substrate, and the organic resin layer is between a side surface of the barrier wall and a side surface of the front substrate. The color conversion panel includes: a thin film encapsulation layer on the organic resin layer.

The barrier wall may include a first width at a first distance from the light source panel and a second width at a second distance from the light source panel, the first width is greater than the second width, and the first distance is less than the second distance. The organic resin layer may include a third width at a third distance from the light source panel and a fourth width at a fourth distance from the light source panel, the third width is less than the fourth width, and the third distance is less than the fourth distance.

The barrier wall may include an inclined side surface having a shape of an inverse taper. The organic resin layer may include an inclined surface having a shape of a positive taper.

The front substrate may include: a plurality of side surfaces; and a first surface bent from the plurality of side surfaces. The barrier wall may include an inclined side surface having an obtuse angle with the first surface. The organic resin layer may include an inclined surface having an acute angle with the first surface.

The front substrate further may include a corner surface between at least one of the plurality of side surfaces and the first surface, and the corner surface having an inclined or round shape.

The thin film encapsulation layer may include: a first thin film encapsulation layer on the corner surface of the front substrate; and a second thin film encapsulation layer on a side surface of the organic resin layer. The organic resin layer may be between the first thin film encapsulation layer and the second thin film encapsulation layer.

The display may include: an overcoat layer on the front substrate. A side surface of the overcoat layer may overlap the organic resin layer and may protrude further toward the side surface of the front substrate than the barrier wall.

The organic resin layer may include the same material as the overcoat layer or a liquid-repellent material.

The display may include at least one trench between the barrier wall, the at least one trench separating the plurality of sub-pixels located at the outermost position of the front substrate and the side surface of the front substrate.

The at least one trench may correspond to the plurality of sub-pixels in a one-to-many manner.

The at least one trench may correspond to the plurality of sub-pixels in a one-to-one manner.

The display may include a side encapsulation layer on a side surface of the light source panel and a side surface of the color conversion panel.

The display may include a side planarization layer between at least one of the side surface of the light source panel or the side surface of the color conversion panel and the side encapsulation layer.

The display may include: a side protection member on the side encapsulation layer.

At least one of the thin film encapsulation layer or the side encapsulation layer may include at least one layer structure including at least one of Al2O3, SiNx, SiOx, or SiON.

According to an aspect of the disclosure, a color conversion panel includes: a front substrate; color conversion layers on the front substrate; a barrier wall between the color conversion layers on the front substrate; an organic resin layer on a side surface of the barrier wall. The organic resin layer separates a plurality of sub-pixels at an outermost position of the front substrate, and the organic resin layer is between a side surface of the barrier wall and a side surface of the front substrate. The color conversion panel includes a thin film encapsulation layer on the organic resin layer.

The barrier wall may include a first width at a first distance from the front substrate and a second width at a second distance from the front substrate, the first width is less than the second width, and the first distance is less than the second distance. The organic resin layer may include a third width at a third distance from the front substrate and a fourth width at a fourth distance from the front substrate, the third width is greater than the fourth width, and the third distance is less than the fourth distance.

The front substrate may include: a plurality of side surfaces; a first surface bent from the plurality of side surfaces; and a corner surface between at least one of the plurality of side surfaces and the first surface and having an inclined or round shape.

The thin film encapsulation layer may include: a first thin film encapsulation layer on the corner surface of the front substrate; and a second thin film encapsulation layer on a side surface of the organic resin layer. The organic resin layer is between the first thin film encapsulation layer and the second thin film encapsulation layer.

The color conversion panel may include an overcoat layer on the front substrate. A side surface of the overcoat layer may overlap the organic resin layer and protrudes further toward the side surface of the front substrate than the side surface of the barrier wall.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a schematic plan view illustrating a display according to one or more embodiments of the disclosure;

FIG. 2 is a schematic sectional view illustrating the display according to one or more embodiments of the disclosure;

FIG. 3 is a perspective view illustrating a color conversion panel according to one or more embodiments of the disclosure;

FIG. 4 is a sectional view illustrating the color conversion panel according to one or more embodiments of the disclosure;

FIG. 5 is a sectional view illustrating the color conversion panel according to one or more embodiments of the disclosure;

FIG. 6 is a sectional view illustrating a color conversion panel according to one or more embodiments of the disclosure;

FIG. 7 is a sectional view illustrating a color conversion panel according to one or more embodiments of the disclosure;

FIG. 8 is a sectional view illustrating a color conversion panel according to one or more embodiments of the disclosure;

FIGS. 9A, 9B, 9C, and 9D, are sectional views illustrating a method of manufacturing a color conversion panel according to one or more embodiments of the disclosure;

FIG. 10 is a view illustrating a method of manufacturing a color conversion panel according to one or more embodiments of the disclosure;

FIG. 11 is a view illustrating a method of manufacturing a color conversion panel according to one or more embodiments of the disclosure;

FIG. 12 is a view illustrating a method of manufacturing a color conversion panel according to one or more embodiments of the disclosure;

FIG. 13 is a view illustrating a method of manufacturing a color conversion panel according to one or more embodiments of the disclosure;

FIG. 14 is a view illustrating a method of manufacturing a color conversion panel according to one or more embodiments of the disclosure;

FIG. 15A is a plan view illustrating a color conversion panel according to one or more embodiments of the disclosure before a second area is removed,;

FIG. 15B is a plan view illustrating the color conversion panel after the second area is removed according to one or more embodiments of the disclosure;

FIGS. 16A and 16B are sectional views illustrating a method of manufacturing a display including a color conversion panel according to one or more embodiments of the disclosure;

FIGS. 17A and 17B are sectional views illustrating a method of manufacturing a display including a color conversion panel according to one or more embodiments of the disclosure; and

FIG. 18 is a view illustrating a display according to one or more embodiments.

### DETAILED DESCRIPTION

Hereinafter, embodiments of the disclosure will be described with reference to the accompanying drawings.

One or more embodiments of the disclosure to be described below provide a display of a large-area electronic device that is capable of supporting moisture penetration prevention performance.

Further, one or more embodiments of the disclosure provide a modular display capable of implementing a narrow bezel while improving the performance of preventing moisture penetration through a side surface of a color conversion panel.

Furthermore, one or more embodiments of the disclosure provide a display including a color conversion panel capable of reducing non-uniformity in printing quality of a color conversion layer of the outermost sub-pixels.

Moreover, one or more embodiments of the disclosure may be applied to a TV, a monitor for a personal computer (PC), a video wall, a large format display (LFD), a digital signage, a digital information display (DID), and a projector display.

In addition, in one or more embodiments of the disclosure, a plurality of displays (or, display panels) may be implemented in the form of a matrix (or, a module) and may be applied to various display devices through a plurality of assembly arrangements.

Various effects provided by a display of a large-area electronic device according to one or more embodiments may be mentioned according to embodiments in the detailed description.

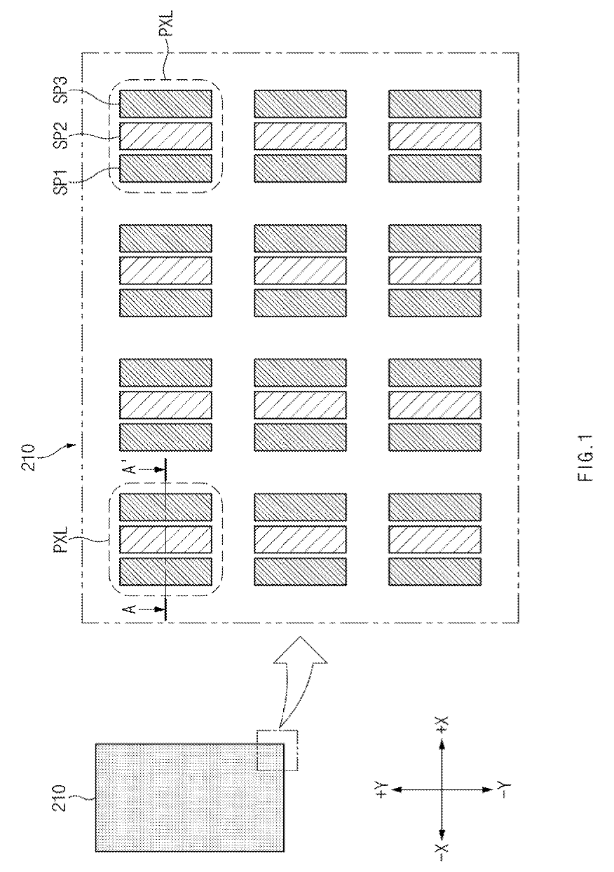

FIG. 1 is a schematic plan view illustrating a display according to one or more embodiments of the disclosure.

Referring to FIG. 1, the display 210 may include a plurality of pixels PXL that display an image. Each pixel PXL may include a plurality of sub-pixels SP1, SP2, and SP3 that emit light of different colors. For example, each of the plurality of pixels PXL may include a first sub-pixel SP1 that implements red, a second sub-pixel SP2 that implements green, and a third sub-pixel SP3 that implements blue. In one or more embodiments, each of the plurality of pixels PXL may include the first to third sub-pixels SP1, SP2, and SP3 and a fourth sub-pixel that emits white light. An image may be displayed on the display 210 by controlling the amount of light emitted from each of the sub-pixels SP1, SP2, and SP3.

According to one or more embodiments, the plurality of pixels PXL are illustrated as being arranged in the order of the first sub-pixel SP1 that implements red, the second sub-pixel SP2 that implements green, and the third sub-pixel SP3 that implements blue, but are not limited thereto. Various changes may be made depending on the design.

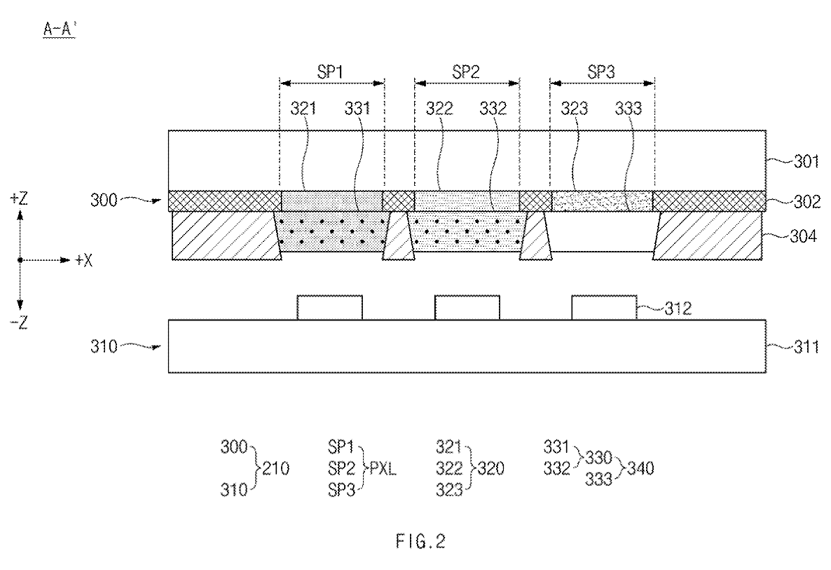

FIG. 2 is a schematic sectional view illustrating the display according to one or more embodiments of the disclosure. FIG. 2 is a schematic sectional view of the display taken along line A-A’ in FIG. 1.

Referring to FIG. 2, the display 210 may include a light source panel 310 (or, a light source substrate, a light source module, or a light source assembly) and a color conversion panel 300 (or, a color conversion substrate, a color conversion module, or a color conversion assembly) that faces the light source panel 310. Although the light source panel 310 and the color conversion panel 300 illustrated in FIG. 2 are illustrated as being spaced apart from each other, the light source panel 310 and the color conversion panel 300 may be bonded to each other through a bonding agent.

The light source panel 310 may be embodied as a substrate that generates and emits light necessary to display an image. The light source panel 310 may include a rear substrate 311, a light emitting element 312, and a pixel circuit that drives the light emitting element.

The rear substrate 311 may be embodied as a plastic substrate or a glass substrate. The rear substrate 311 may have flexible characteristics. The light emitting element 312 and the pixel circuit may be disposed on the rear substrate 311. The light emitting element 312 may be disposed to overlap a color filter 320 disposed on a front substrate 301, and at least a part of the pixel circuit (e.g., a signal line and a transistor) may be disposed to overlap a black matrix 302 disposed on the front substrate 301.

The light emitting element 312 may include at least one of an organic light emitting diode, a quantum-dot light emitting diode, an inorganic material-based micro light emitting diode (Micro LED), or an inorganic material-based nano light emitting diode (nano LED). For example, the light emitting element 312 may be a micro light emitting diode.

The pixel circuit may include a plurality of transistors. in one or more embodiments, the pixel circuit may be implemented with a CMOS circuit including a combination of at least one N-type transistor and at least one P-type transistor.

The color conversion panel 300 may include the front substrate 301, the color filter 320, a barrier wall 304, a color control member 340, and the black matrix 302.

The front substrate 301 may include a light transmitting material. The front substrate 301 may be a plastic substrate or a glass substrate. The front substrate 301 may have flexible characteristics. The color filter 320, the barrier wall 304, a color conversion member 330, a transparent layer 333, and the black matrix 302 may be stacked on an opposite surface (e.g., the surface facing in the -Z-axis direction) of the front substrate 301. Since light passing through the color filter 320 is emitted to the outside through one surface (e.g., the surface facing in the +Z-axis direction) of the front substrate 301, an image may be provided to a viewer looking at the display.

The color filter 320 may include a first color filter 321, a second color filter 322, and a third color filter 323. The first color filter 321 may implement the same color as light emitted from a first color conversion layer 331. For example, the first color filter 321 may be a red color filter. The first color filter 321 may transmit red light and may absorb light of other colors other than the red light. The first color filter 321 may increase the color purity of the red light incident through the first color conversion layer 331. The second color filter 322 may implement the same color as light emitted from a second color conversion layer 332. For example, the second color filter 322 may be a green color filter. The second color filter 322 may transmit green light and may absorb light of other colors other than the green light. The second color filter 322 may increase the color purity of the green light incident through the second color conversion layer 332. The third color filter 323 may implement the same color as light emitted from the light emitting element 312. For example, the third color filter 323 may be a blue color filter. The third color filter 323 may transmit blue light and may absorb light of other colors other than the blue light. The third color filter 323 may increase the color purity of the blue light incident through the transparent layer 333.

The black matrix 302 may be disposed between the first color filter 321, the second color filter 322, and the third color filter 323. Since the black matrix 302 divides the areas of the sub-pixels SP1, SP2, and SP3 from each other, the black matrix 302 may overlap the barrier wall 304. The black matrix 302 may include a material such as a metal, a synthetic resin, synthetic rubber, or a carbon-based organic material. For example, the black matrix 302 may include chromium (Cr), chromium oxide (CrOx), carbon black, or a double layer including the same.

The color control member 340 may include the color conversion member 330 and the transparent layer 333. The color conversion member 330 may include the first color conversion layer 331 and the second color conversion layer 332. The first color conversion layer 331 may be formed to overlap the first color filter 321. The first color conversion layer 331 may be disposed between the light emitting element 312 and the first color filter 321. The first color conversion layer 331 may convert light emitted from the light emitting element 312 into light of a first color using a first quantum dot. For example, the first color conversion layer 331 may convert blue light emitted from the light emitting element 312 into red light.

The second color conversion layer 332 may be formed to overlap the second color filter 322. The second color conversion layer 332 may be disposed between the light emitting element 312 and the second color filter 322. The second color conversion layer 332 may convert light emitted from the light emitting element 312 into light of a second color using a second quantum dot. For example, the second color conversion layer 332 may convert blue light emitted from the light emitting element 312 into green light.

The transparent layer 333 may be formed to overlap the third color filter 323. The transparent layer 333 may be disposed between the light emitting element 312 and the third color filter 323. The transparent layer 333 may transmit light emitted from the light emitting element 312 without color conversion. According to one or more embodiments, the transparent layer 333 may be hollow such that incident light passes as it is and may include a transparent resin such as acryl-nitrile butadiene styrene (ABS), poly methyl methacrylate (PMMA), or poly carbonate (PC). According to one or more embodiments, the transparent layer 333 may include a transparent resin and a scattering material. The scattering material may be TiO₂, SiO₂, or/and glass bead.

The barrier wall 304 may be formed to separate the sub-pixels SP1, SP2, and SP3 that implement different colors. The barrier wall 304 may block the movement of light between the sub-pixels SP1, SP2, and SP3 that implement different colors. The barrier wall 304 may have a black color that absorbs light. The barrier wall 304 may include a material such as a metal, a synthetic resin, synthetic rubber, or a carbon-based organic material. In one or more embodiments, the barrier wall 304 may include chromium (Cr), chromium oxide (CrOx), carbon black, or a double layer including the same. The barrier wall 304 may be formed such that the thickness of the color control member 340 is secured by a specified thickness or more. in one or more embodiments, the barrier wall 304 may be formed to have a thickness of 10 μm to 15 μm in consideration of the thickness of the color control member 340.

The barrier wall 304 may include a side surface in contact with an opposite surface (e.g., the surface facing in the -Z-axis direction) of the black matrix 302. The barrier wall 304 may be formed in a taper shape including a side surface perpendicular to the opposite surface of the black matrix 302 or having a side surface inclined with respect to the opposite surface of the black matrix 302.

According to one or more embodiments, the color conversion panel 300 may be completed by sequentially forming the black matrix 302, the color filter 320, and the barrier wall 304 and then forming the color conversion member 330 and the transparent layer 333, which are included in the color control member 340, through an electrohydrodynamic (EHD) process or an inkjet process.

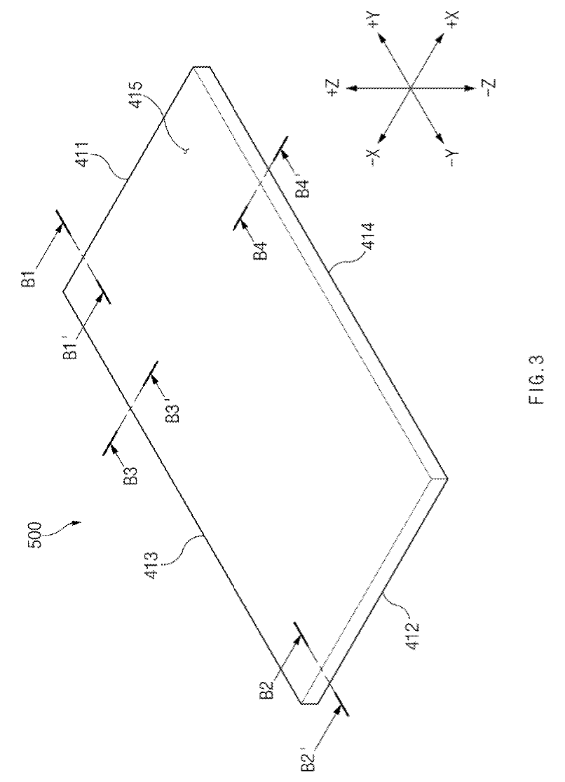

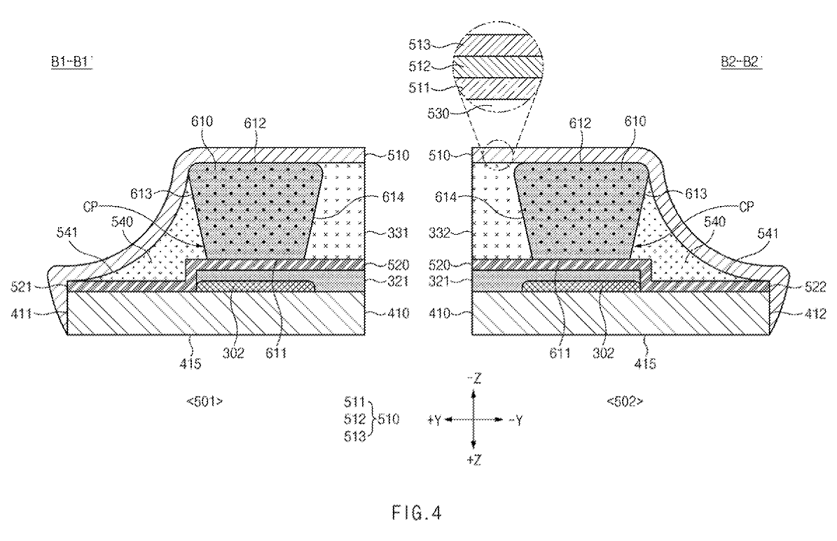

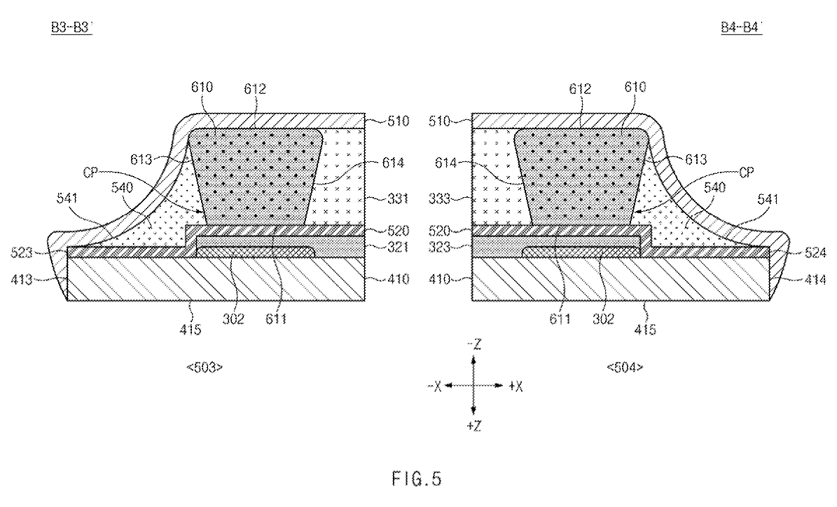

FIG. 3 is a perspective view illustrating a color conversion panel according to one or more embodiments, and FIGS. 4 and 5 are sectional views illustrating the color conversion panel according to one or more embodiments. In FIG. 4, drawing 501 is a sectional view of the color conversion panel taken along line B1-B1’ in FIG. 3, and drawing 502 is a sectional view of the color conversion panel taken along line B2-B2’ in FIG. 3. In FIG. 5, drawing 503 is a sectional view of the color conversion panel taken along line B3-B3’ in FIG. 3, and drawing 504 is a sectional view of the color conversion panel taken along line B4-B4’ in FIG. 3. In FIGS. 3, 4, and 5, the color conversion panel applied to the electronic device described above will be described as an example.

Referring to FIGS. 3, 4, and 5, the color conversion panel 500 according to one or more embodiments (e.g., the color conversion panel 300 of FIG. 2) may include a front substrate 410 (e.g., the front substrate 301 of FIG. 2), a black matrix 302, a color filter 320, an overcoat layer 520, a barrier wall 610 (e.g., the barrier wall 304 of FIG. 1), color conversion layers 331, 332, and 333, a thin film encapsulation layer 510, and an organic resin layer 540 (or, a side resin layer). In describing the embodiment of FIGS. 3, 4, and 5, reference may be made to the color conversion panel of the embodiment illustrated in FIG. 2, components similar or identical to those of the embodiment illustrated in FIG. 2 will be assigned with the same reference numerals or omitted, and detailed description thereof may also be omitted.

The front substrate 410 may include a first side surface 411, a second side surface 412, a third side surface 413, and a fourth side surface 414. The first side surface 411 of the front substrate 410 may face the second side surface 412. The first side surface 411 may face in the +Y-axis direction, and the second side surface 412 may face in the -Y-axis direction. The third side surface 413 may intersect the first side surface 411 and may face the fourth side surface 414. The third side surface 413 may face in the -X-axis direction, and the fourth side surface 414 may face in the +X-axis direction. The front substrate 410 may include one surface 415 facing in the +Z-axis direction. At least one of the first side surface 411, the second side surface 412, the third side surface 413, or the fourth side surface 414 may be formed to be bent from the one surface 415 while being in contact with the one surface 415 corresponding to the surface on which an image is implemented in the electronic device. At least one of the first side surface 411, the second side surface 412, the third side surface 413, or the fourth side surface 414 may form an acute angle or a right angle with the one surface 415.

The overcoat layer 520 may be disposed on the black matrix 302 and the color filters 321, 322, and 323 to cover the black matrix 302 and the color filters 321, 322, and 323. The overcoat layer 520 may include an organic insulating material and may flatten steps between the color filters 321, 322, and 323 and the black matrix 302.

The color control member (e.g., the color control member 340 of FIG. 2) may include a first color conversion layer 331, a second color conversion layer 332, and a transparent layer 333. In one or more embodiments, the first color conversion layer 331, the second color conversion layer 332, and the transparent layer 333 may be disposed adjacent to the first side surface 411 and the second side surface 412 of the front substrate 410. The first color conversion layer 331 may be disposed adjacent to the third side surface 413 of the front substrate 410. The transparent layer 333 may be disposed adjacent to the fourth side surface 414 of the front substrate 410.

The thin film encapsulation layer 510 may be formed to cover the color control member including the color conversion layers 331 and 332 vulnerable to external moisture or oxygen. The thin film encapsulation layer 510 may block external moisture or oxygen from penetrating into the color control member including the color conversion layers 331 and 332.

According to one or more embodiments, the thin film encapsulation layer 510 may be formed to cover the first color conversion layer 331, the second color conversion layer 332, the transparent layer 333, the organic resin layer 540, side surfaces 521, 522, 523, and 524 of the overcoat layer 520, and/or the side surfaces 411, 412, 413, and 414 of the front substrate 410. The thin film encapsulation layer 510 may block a moisture penetration path by the first color conversion layer 331, the second color conversion layer 332, the transparent layer 333, the organic resin layer 540, the side surfaces 521, 522, 523, and 524 of the overcoat layer 520, and/or the side surfaces 411, 412, 413, and 414 of the front substrate 410.

In one or more embodiments, the thin film encapsulation layer 510 may be formed in at least one layer structure including an inorganic insulating material. The thin film encapsulation layer 510 may be formed in at least one layer structure including at least one of Al₂O₃, SiNx, SiOx, or SiON. The thin film encapsulation layer 510 may be formed by an atomic layer deposition (ALD) method, a chemical vapor deposition (CVD) method, or/and a plasma enhanced chemical vapor deposition (PFC) method.

According to one or more embodiments, the thin film encapsulation layer 510 may be formed in a single-layer structure by depositing Al₂O₃ using an ALD method. According to one or more embodiments, the thin film encapsulation layer 510 may be formed in a single-layer or a multi-layer structure by depositing at least one of SiNx, SiOx, or SiON using a CVD or PECVD method.

According to one or more embodiments, the uppermost layer of the thin film encapsulation layer 510 having a multi-layer structure (or, the uppermost layer disposed furthest from the front substrate 410) (e.g., a third encapsulation layer 513) may include a material having a denser structure than the remaining encapsulation layers included in the multi-layered encapsulation layer 510 (e.g., a first encapsulation layer 511 and/or a second encapsulation layer 512). In one or more embodiments, the uppermost layer of the thin film encapsulation layer 510 may include SiNx, and the remaining encapsulation layers of the thin film encapsulation layer 510 may include SiOx or/and SiON. Since the uppermost layer of the thin film encapsulation layer 510 has a denser structure than the remaining encapsulation layers of the thin film encapsulation layer 510, the uppermost layer of the thin film encapsulation layer 510 may be resistant to moisture. Since the remaining encapsulation layers have a less dense structure when compared to the uppermost layer of the thin film encapsulation layer 510, the remaining encapsulation layers may alleviate the compressive stress occurring in the uppermost layer, thereby preventing the thin film encapsulation layer 510 from being damaged by the uppermost layer.

According to one or more embodiments, the thin film encapsulation layer 510 may be formed in a multi-layer structure by depositing SiON or/and SiOx using a PECVD method and then depositing SiNx using a PECVD method.

According to one or more embodiments, the thin film encapsulation layer 510 may be formed in a single-layer structure or a multi-layer structure by depositing at least one of Al₂O₃, SiNx, SiOx, or SiON using a CVD or PECVD method and an ALD method. In one or more embodiments, the thin film encapsulation layer 510 may be formed in a multi-layer structure by depositing Al₂O₃using an ALD method and then sequentially depositing SiON and SiNx using a PECVD method. The thin film encapsulation layer 510 may include the first encapsulation layer 511 formed of Al₂O₃, the second encapsulation layer 512 disposed on the first encapsulation layer 511 and formed of SiON, and the third encapsulation layer 513 disposed on the second encapsulation layer 512 and formed of SiNx.

The barrier wall 610 may include one surface 611 (or, a first barrier wall surface) (e.g., the surface facing in the +Z-axis direction) adjacent to the overcoat layer 520, an opposite surface 612 (or, a second barrier wall surface) (e.g., the surface facing in the -Z-axis direction) adjacent to the thin film encapsulation layer 510, and a first inclined side surface 613 (or, a third barrier wall surface) and a second inclined side surface 614 (or, a fourth barrier wall surface) that are disposed between the one surface and the opposite surface.

The surface area of the one surface 611 of the barrier wall 610 (or, the contact area with the overcoat layer 520) may be smaller than the surface area of the opposite surface 612 of the barrier wall 610 (or, the contact area with the thin film encapsulation layer 510). The first inclined side surface 613 of the barrier wall 610 formed along the periphery of the front substrate 410 may be disposed adjacent to the side surfaces 411, 412, 413, and 414 of the front substrate 410, and the second inclined side surface 614 of the barrier wall 610 may be disposed away from the side surfaces 411, 412, 413, and 414 of the front substrate 410.

According to one or more embodiments, the first inclined side surface 613 formed along the periphery of the front substrate 410 and located at the outermost position of the barrier wall 610 may make contact with the organic resin layer 540, and the second inclined side surface 614 may make contact with the color control layers 331, 332, and 333. The first inclined side surface 613 and the second inclined side surface 614 of the barrier wall 610 located inward of the periphery of the front substrate 410 may make contact with the color control layers 331, 332, and 333.

According to one or more embodiments, the barrier wall 610 may be formed in the shape of a negative taper or an inverse taper. The barrier wall 610 may have a gradually increasing width farther away from the front substrate 410. The width of the barrier wall 610 may be gradually increased from the one surface facing toward the front substrate 410 (e.g., the surface facing in the +Z-axis direction) toward the opposite surface facing toward the light source panel (e.g., the light source panel 310 of FIG. 2) (e.g., the surface facing in the -Z-axis direction). The angle formed by at least one of the first inclined side surface 613 or the second inclined side surface 614 of the barrier wall 610 having the shape of an inverse taper and the one surface 611 may be an obtuse angle. The angle formed by at least one of the first inclined side surface 613 or the second inclined side surface 614 of the barrier wall 610 having the shape of an inverse taper and the opposite surface 612 may be an acute angle.

According to one or more embodiments, light passing through the color control layers 331, 332, and 333 may be widely radiated and emitted toward the front substrate 410 without being lost by the barrier wall 610 having the shape of an inverse taper. Meanwhile, in the case of a barrier wall having the shape of a positive taper, light generated from the light source panel and passing through the color control layers 331, 332, and 333 may be reflected by the barrier wall having the shape of a positive taper and may return toward the light source panel (e.g., the light source panel 310 of FIG. 2) without being emitted through the front substrate 410. Accordingly, in consideration of luminous efficiency, the barrier wall 610 formed of an opaque material may be formed in the shape of an inverse taper having the inclined side surfaces 613 and 614 that are spaced farther away from a virtual central axis of the barrier wall 610 from the one surface 611 toward the opposite surface 612.

According to one or more embodiments, the color control layers 331, 332, and 333 may be formed after the barrier wall 610 is formed. Since the barrier wall 610 is formed in the shape of an inverse taper, the color control layers 331, 332, and 333 may be separated by the barrier wall 610 even though the color control layers 331, 332, and 333 are formed using a common mask.

According to one or more embodiments, the organic resin layer 540 may be formed to make contact with the first inclined side surface 613 located at the outermost position of the barrier wall 610 formed along the periphery of the front substrate 410. The organic resin layer 540 may be formed to cover the first inclined side surface 613 of the barrier wall 610 having the shape of an inverse taper. The organic resin layer 540 may be formed by being applied to cover a corner portion CP formed by the first inclined side surface 613 of the barrier wall 610 that surrounds the outermost sub-pixel (e.g., the sub-pixel SP of FIG. 2) and an opposite surface (e.g., the surface facing in the -Z-axis direction) of the overcoat layer 520. The organic resin layer 540 may be formed in a form that fills the corner portion CP.

A side surface 541 of the organic resin layer 540 may have a shape symmetrical to the first inclined side surface 613 of the barrier wall 610. The side surface 541 (or, the first inclined surface) of the organic resin layer 540 that makes contact with the thin film encapsulation layer 510 may be formed in the shape of a positive taper. The side surface 541 of the organic resin layer 540 may form an acute angle with the opposite surface of the overcoat layer 520 and may form an obtuse angle with the opposite surface 612 of the barrier wall 610. The thin film encapsulation layer 510 disposed on the organic resin layer 540 including a portion having the shape of a positive taper may be formed to have a uniform thickness over the entire area of the thin film encapsulation layer 510. Since the thin film encapsulation layer 510 disposed on the organic resin layer 540 is formed to be gentle in the area corresponding to the corner portion CP, the thin film encapsulation layer 510 may be formed to have a uniform thickness without disconnection in the area corresponding to the corner portion CP. The step coverage of the thin film encapsulation layer 510 formed on the organic resin layer 540 may be improved, and thus moisture penetration through the side surface of the thin film encapsulation layer 510 may be prevented.

The organic resin layer 540 may include an organic resin material that is transparent or opaque. For example, the organic resin layer 540 may be formed in a single-layer structure or a multi-layer structure with the same material as at least one of the overcoat layer 520, the barrier wall 610, the color filter 321, 322, and 323, the first color conversion layer 331, the second color conversion layer 332, the transparent layer 333, or a liquid-repellent material. The organic resin layer 540 may be formed through an electrohydrodynamic (EHD) process or an inkjet process.

According to one or more embodiments, when the organic resin layer 540 is formed of a colored (e.g., red, green, or/and blue) organic resin material, the black matrix 302 may be formed to overlap the organic resin layer 540. The black matrix 302 overlapping the organic resin layer 540 may prevent light from being emitted to the outside of the color conversion panel 500 through the organic resin layer 540, thereby preventing crosstalk defects.

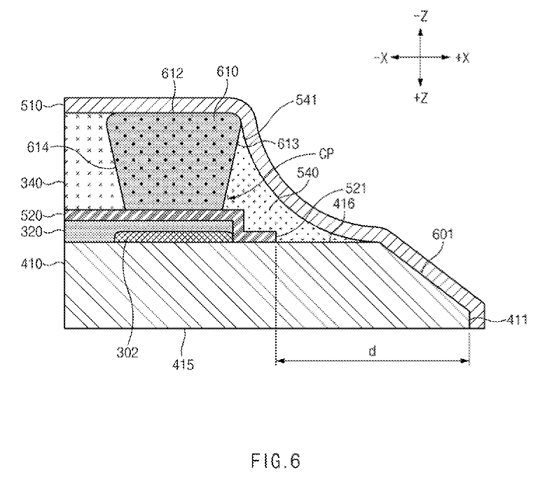

FIG. 6 is a sectional view illustrating a color conversion panel according to one or more embodiments. In FIG. 6, the color conversion panel applied to the electronic device described above will be described as an example.

Referring to FIG. 6, the color conversion panel according to one or more embodiments (e.g., the color conversion panel 300 of FIG. 2 or/and the color conversion panel 500 of FIGS. 3, 4, and 5,may include a front substrate 410, a black matrix 302, a color filter 320, an overcoat layer 520, a barrier wall 610, a color control member 340, a thin film encapsulation layer 510, and an organic resin layer 540. The description of at least some components of the color conversion panels of FIGS. 2, 3, 4, and 5, may be applied to at least some components of the color conversion panel of FIG. 6. In one or more embodiments, the description of the black matrix 302, the color filter 320, the overcoat layer 520, the barrier wall 610, the color control member 340, the thin film encapsulation layer 510, and the organic resin layer 540 of FIGS. 2, 3, 4, and 5, may be applied to the black matrix 302, the color filter 320, the overcoat layer 520, the barrier wall 610, the color control member 340, the thin film encapsulation layer 510, and the organic resin layer 540 of FIG. 6.

The front substrate 410 may include one surface 415 (or, a second surface), an opposite surface 416 (a first surface) facing away from the one surface 415, a first side surface 411, a second side surface (e.g., the second side surface 412 of FIG. 3), a third side surface (e.g., the third side surface 413 of FIG. 3), and a fourth side surface (e.g., the fourth side surface 414 of FIG. 3). A corner surface 601 (or, a chamfered surface or a second inclined surface) may be formed between at least a portion of at least one of the first side surface 411, the second side surface, the third side surface, or the fourth side surface and the opposite surface 416. The corner surface 601 may be formed in the shape of a curved surface or an inclined surface. One side of the corner surface 601 may be formed to be bent from the side surface 411 while being in contact with the side surface 411. The one side of the corner surface 601 may form an obtuse angle with the side surface 411. An opposite side of the corner surface 601 may be formed to be bent from the opposite surface 416 while being in contact with the opposite surface 416. The opposite side of the corner surface 601 may form an obtuse angle with the opposite surface 416.

The corner surface 601 may be formed in an inclined or curved shape by performing a chamfer process or a corner rounding process on a corner portion of the front substrate 410. In one or more embodiemnts, the corner surface 601 may have a length of 10 μm to 50 μm.

The overcoat layer 520 may include a side surface 521 facing in the same direction as at least one of the first side surface 411, the second side surface, the third side surface, or the fourth side surface of the front substrate 410. The side surface 521 of the overcoat layer 520 may be spaced apart from the side surface 411 of the front substrate 410 by a specified distance d. The side surface 521 of the overcoat layer 520 may be spaced apart from the side surface 411 of the front substrate 410 in a first direction (e.g., the +X-axis direction) and/or a second direction (e.g., the +Y-axis direction). The side surface 521 of the overcoat layer 520 may be formed to protrude further toward the side surface 411 of the front substrate 410 than a first inclined side surface 613 of the barrier wall 610. In one or more embodiments, the side surface 521 of the overcoat layer 520 may be formed to protrude further than the first inclined side surface 613 of the barrier wall 610 by about 20 μm or less. The side surface 521 of the overcoat layer 520 may be formed to overlap the organic resin layer 540.

The side surface 521 of the overcoat layer 520 formed of an organic insulating material (e.g., a polymer) may be located further inside the color conversion panel than the side surface 411 of the front substrate 410. The side surface 521 of the overcoat layer 520 may be prevented from being used as a moisture penetration path. Even though the thin film encapsulation layer 510 is damaged at the edge of the front substrate 410 and moisture penetrates through the damaged gap of the thin film encapsulation layer 510, external moisture or oxygen may be prevented from penetrating into the overcoat layer 520.

The thin film encapsulation layer 510 may be formed to cover the color control member 340 including color conversion layers 331 and 332 vulnerable to external moisture or oxygen. The thin film encapsulation layer 510 may block external moisture or oxygen from penetrating into the color control member 340 including the color conversion layers 331 and 332.

According to one or more embodiments, the thin film encapsulation layer 510 may be formed to cover the color control member 340, the organic resin layer 540, and/or the side surfaces 411, 412, 413, and 414 of the front substrate 410. The thin film encapsulation layer 510 may block a moisture penetration path by the color control member 340, a side surface 541 (or, a first inclined surface) of the organic resin layer 540, the corner surface 601 (or, the second inclined surface) of the front substrate 410, and the side surface 411 of the front substrate 410.

The organic resin layer 540 may be formed to cover the first inclined side surface 613 of the barrier wall 610 having the shape of an inverse taper. The organic resin layer 540 may be formed by being applied to cover a corner portion CP formed by the first inclined side surface 613 of the barrier wall 610 that surrounds the outermost sub-pixel (e.g., the sub-pixel SP of FIG. 2) and an opposite surface (e.g., the surface facing in the -Z-axis direction) of the overcoat layer 520. The thin film encapsulation layer 510 disposed on the organic resin layer 540 may be formed to have a uniform thickness over the entire area of the thin film encapsulation layer 510. Since the thin film encapsulation layer 510 disposed on the organic resin layer 540 is formed to be gentle in the area corresponding to the corner portion CP and the corner surface 601, the thin film encapsulation layer 510 may be formed to have a uniform thickness without disconnection in the area corresponding to the corner portion CP. The step coverage of the thin film encapsulation layer 510 formed on the organic resin layer 540 may be improved, and thus moisture penetration into the thin film encapsulation layer 510 may be prevented.

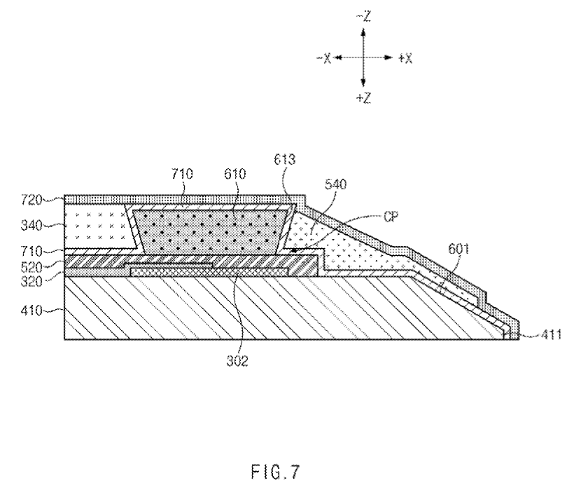

FIG. 7 is a sectional view illustrating a color conversion panel according to one or more embodiments. In FIG. 7, the color conversion panel applied to the electronic device described above will be described as an example.

Referring to FIG. 7, the color conversion panel according to one or more embodiments (e.g., the color conversion panel 300 of FIG. 2 or/and the color conversion panel 500 of FIGS. 3, 4, and 5, may include a front substrate 410, a black matrix 302, a color filter 320, an overcoat layer 520, a barrier wall 610, a color control member 340 (e.g., the first color conversion layer 331, the second color conversion layer 332, or/and the transparent layer 333 of FIG. 2), a first thin film encapsulation layer 710, a second thin film encapsulation layer 720, and an organic resin layer 540. The description of at least some components of the color conversion panels of FIGS. 2, 3, 4, 5, and 6, may be applied to at least some components of the color conversion panel of FIG. 7. For example, the description of the black matrix 302, the color filter 320, the overcoat layer 520, the barrier wall 610, and the color control member 340 of FIGS. 2, 3, 4, 5, and 6, may be applied to the black matrix 302, the color filter 320, the overcoat layer 520, the barrier wall 610, and the color control member 340 of FIG. 7.

The first thin film encapsulation layer 710 may be formed to contact with one surface (e.g., the surface facing in the +Z-axis direction) of the color control member 340. The first thin film encapsulation layer 710 may block external moisture or oxygen from penetrating through the one surface of the color control member 340.

The second thin film encapsulation layer 720 may be formed to contact with an opposite surface (e.g., the surface facing in the -Z-axis direction) of the color control member 340. The second thin film encapsulation layer 720 may block external moisture or oxygen from penetrating through the opposite surface of the color control member 340.

The organic resin layer 540 may be formed between the first thin film encapsulation layer 710 and the second thin film encapsulation layer 720. The organic resin layer 540 may be formed by being applied to cover a corner portion CP formed by a portion of the first thin film encapsulation layer 710 on a first inclined side surface 613 of the barrier wall 610 that surrounds the outermost sub-pixel (e.g., the sub-pixel SP of FIG. 2) and a portion of the first thin film encapsulation layer 710 on an opposite surface (e.g., the surface facing in the -Z-axis direction) of the overcoat layer 520.

The second thin film encapsulation layer 720 disposed on the organic resin layer 540 may be formed to have a uniform thickness over the entire area of the second thin film encapsulation layer 720. Since the second thin film encapsulation layer 720 disposed on the organic resin layer 540 is formed to be gentle in the area corresponding to the corner portion CP and a corner surface 601, the second thin film encapsulation layer 720 may be formed to have a uniform thickness without disconnection in the area corresponding to the corner portion CP. The step coverage of the second thin film encapsulation layer 720 formed on the organic resin layer 540 may be improved, and thus moisture penetration into the second thin film encapsulation layer 720 may be prevented.

According to one or more embodiments, at least one of the first thin film encapsulation layer 710 or the second thin film encapsulation layer 720 may be formed in at least one layer structure made of an inorganic insulating material. At least one of the first thin film encapsulation layer 710 or the second thin film encapsulation layer 720 may be formed in at least one layer structure including at least one of Al₂O₃, SiNx, SiOx, or SiON. The second thin film encapsulation layer 720 may include a material having a denser structure than the first thin film encapsulation layer 710. For example, the second thin film encapsulation layer 720 may include SiNx, and the first thin film encapsulation layer 710 may include SiOx or/and SiON.

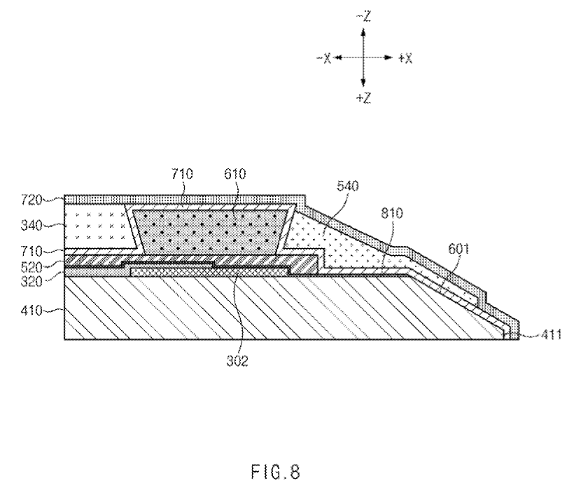

FIG. 8 is a sectional view illustrating a color conversion panel according to one or more embodiments. In FIG. 8, the color conversion panel applied to the electronic device described above will be described as an example.

Referring to FIG. 8, the color conversion panel according to one or more embodiments (e.g., the color conversion panel 300 of FIG. 2 or/and the color conversion panel 500 of FIGS. 3, 4, and 5, may include a front substrate 410, a black matrix 302, a color filter 320, an overcoat layer 520, a barrier wall 610, a color control member 340 (e.g., the first color conversion layer 331, the second color conversion layer 332, or/and the transparent layer 333 of FIG. 2), a first thin film encapsulation layer 710, a second thin film encapsulation layer 720, an organic resin layer 540, and a transparent conductive layer 810. The description of at least some components of at least one of the color conversion panels of FIGS. 2, 3, 4, 5, 6, and 7,may be applied to at least some components of the color conversion panel of FIG. 8. For example, the description of the black matrix 302, the color filter 320, the overcoat layer 520, the barrier wall 610, the color control member 340, the first thin film encapsulation layer 710, and the second thin film encapsulation layer 720 of FIG. 7 may be applied to the black matrix 302, the color filter 320, the overcoat layer 520, the barrier wall 610, the color control member 340, the first thin film encapsulation layer 710, and the second thin film encapsulation layer 720 of FIG. 8.

The transparent conductive layer 810 may be disposed between the overcoat layer 520 and the front substrate 410. The transparent conductive layer 810 may be formed to cover the color filter 320 and the black matrix 302, each of which is formed of an organic material vulnerable to moisture. The transparent conductive layer 810 may block external moisture or oxygen from penetrating into the color filter 320 and the black matrix 302. The transparent conductive layer 810 may include an inorganic layer resistant to moisture. For example, the transparent conductive layer 810 may include the same inorganic insulating material or inorganic conductive layer as at least one of the first thin film encapsulation layer 710 or the second thin film encapsulation layer 720. The inorganic conductive layer may include a transparent conductive material such as indium tin oxide (ITO).

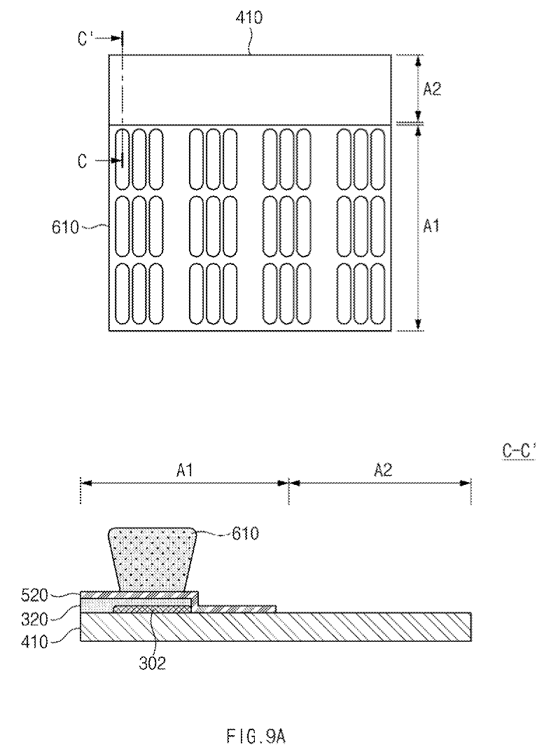

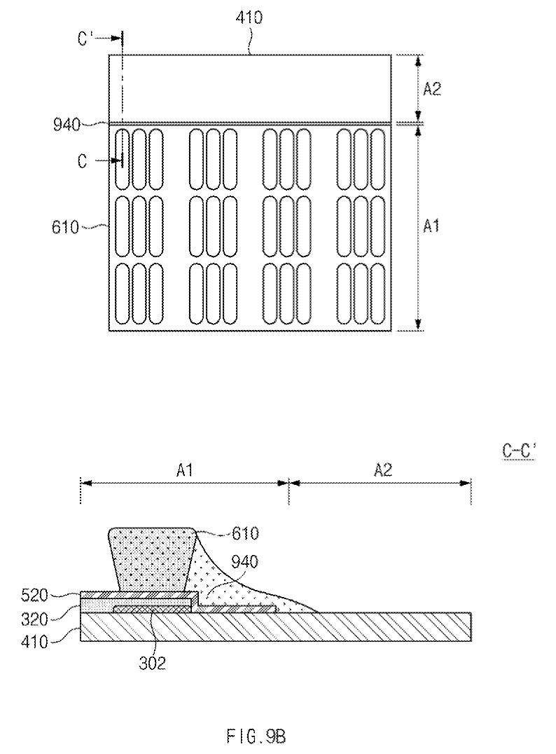

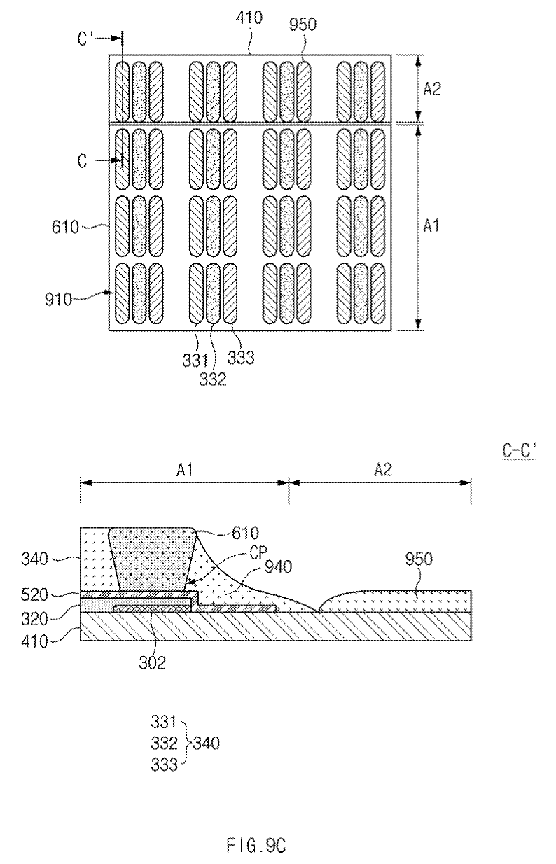

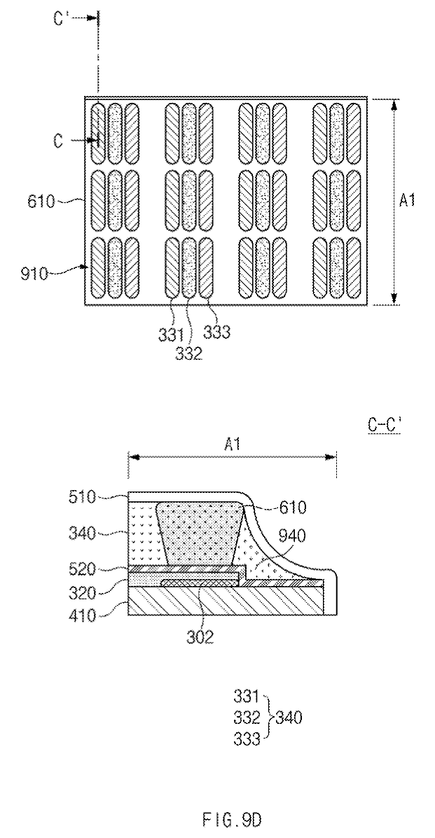

FIGS. 9A, 9B, 9C, and 9D, are sectional views illustrating a method of manufacturing a color conversion panel according to one or more embodiments. In the manufacturing method of FIGS. 9A, 9B, 9C, and 9D, a case in which an organic resin layer is formed of a liquid-repellent material will be described as an example.

Referring to FIG. 9A, a front substrate 410 may include a first area A1 and a second area A2. The first area A1 may be an area where sub-pixels are disposed. The second area A2 may be an outer area disposed outside the first area A1. The second area A2 may be an area capable of being removed after a thin film encapsulation layer (e.g., the thin film encapsulation layer 510 of FIGS. 4, 5, and 6 or the second thin film encapsulation layer 720 of FIGS. 7 and 8) is formed in the first area A1. A black matrix 302, a color filter 320, an overcoat layer 520, and a barrier wall 610 having the shape of an inverse taper may be sequentially formed on the first area A1 of the front substrate 410.

Referring to FIG. 9B, an organic resin layer 940 may be formed on the front substrate 410 on which the barrier wall 610 is formed. The organic resin layer 940 may include a liquid-repellent material between the first area A1 and the second area A2. For example, the organic resin layer 940 may be formed by adding a fluorine-based hydrophobic material to an organic material. The organic resin layer 940 may be formed on a side surface of the barrier wall 610, the overcoat layer 520, and a partial area of the front substrate 410. For example, the organic resin layer 940 may be formed to cover a corner portion CP formed by the side surface of the barrier wall 610 and an opposite surface of the overcoat layer 520. For example, the organic resin layer 940 may be formed on the corner portion CP and an opposite surface 612 of the barrier wall 610 (e.g., the barrier wall 610 of FIG. 6).

Referring to FIG. 9C, a color control member 340 including a first color conversion layer 331, a second color conversion layer 332, and a transparent layer 333 may be formed on the front substrate 410 on which the organic resin layer 940 is formed.

An ink for forming each of the first color conversion layer 331, the second color conversion layer 332, and the transparent layer 333 may be formed not only in the first area A1 but also in the second area A2. Since the ink for forming each of the first color conversion layer 331, the second color conversion layer 332, and the transparent layer 333 is first applied to the second area A2, the unevenness of the ink application amount of the outermost sub-pixel SP formed in the first area A1 may be improved.

The organic resin layer 940 including a fluorine-based hydrophobic material may form a repulsive force with the ink for forming each of the first color conversion layer 331, the second color conversion layer 332, and the transparent layer 333. The color control member 340 including the first color conversion layer 331, the second color conversion layer 332, and the transparent layer 333 that are formed in the first are A1 and a residual ink 950 formed in the second area A2 may be separated by the organic resin layer 940.

Referring to FIG. 9D, a thin film encapsulation layer 510 may be formed on the front substrate 410 on which the first color conversion layer 331, the second color conversion layer 332, and the transparent layer 333 are formed. The thin film encapsulation layer 510 may be formed by applying at least one inorganic insulating layer to the entire surface. After the thin film encapsulation layer 510 is formed, the second area A2 may be separated and removed from the first area A1 through a scribing process.

According to one or more embodiments, after the first color conversion layer 331, the second color conversion layer 332, and the transparent layer 333 are formed, the second area A2 may be cut away from the first area A1 through the scribing process, and then the thin film encapsulation layer 510 may be formed in the first area A1. The thin film encapsulation layer 510 may be formed on the side surface of the front substrate 410 as well as the organic resin layer 940.

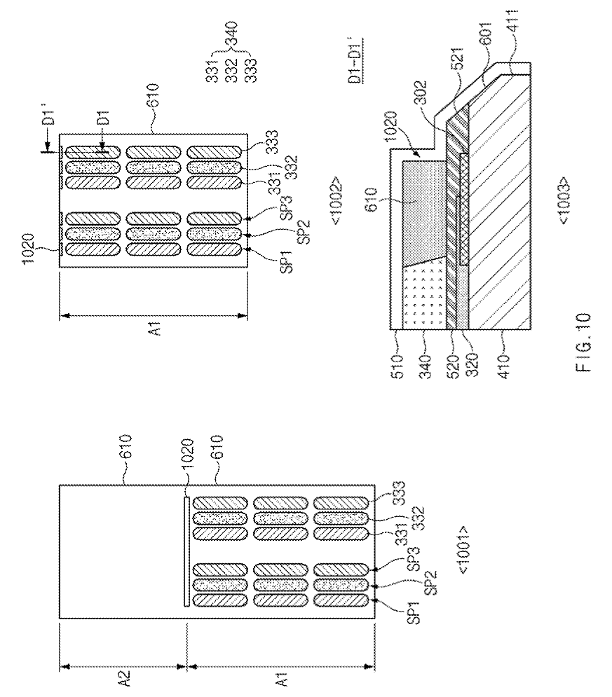

FIG. 10 is a view illustrating a method of manufacturing a color conversion panel according to one or more embodiments. In FIG. 10, drawing 1001 is a plan view illustrating the color conversion panel before a second area A2 is removed, drawing 1002 is a plan view illustrating the color conversion panel after the second area A2 is removed, and drawing 1003 is a sectional view of the color conversion panel taken along line D1-D1’ in drawing 1002.

Referring to FIG. 10, a front substrate 410 may include a first area A1 and the second area A2. The first area A1 may be an area where sub-pixels SP1, SP2, and SP3 are disposed. The second area A2 may be an outer area disposed outside the first area A1. In the second area A2, a barrier wall 610 may be disposed without separate sub-pixels. The second area A2 may be an area capable of being removed after a thin film encapsulation layer 510 is formed in the first area A1.

According to one or more embodiments, before the second area A2 is removed from the first area A1, a trench 1020 may be formed between the first area A1 and the second area A2. The trench 1020 may be formed long from one side to an opposite side of the front substrate 410 in the width direction of each of the sub-pixels SP1, SP2, and SP3. The trench 1020 may be formed along the plurality of sub-pixels in a one-to-many manner. The trench 1020 may be formed between the barrier wall 610 formed in the first area A1 and the barrier wall 610 formed in the second area A2.

After the second area A2 is removed from the first area A1, the trench 1020 may be formed to expose a first inclined side surface of the barrier wall 610.

According to one or more embodiments, an ink for forming each of a first color conversion layer 331, a second color conversion layer 332, and a transparent layer 333 may be formed not only in the first area A1 but also in the second area A2. Since a residual ink formed in the second area A2 is trapped in the trench 1020, the residual ink formed in the second area A2 may not flow into the outermost sub-pixels SP1, SP2, and SP3 of the first area A1 due to the trench 1020. The trench 1020 may block the residual ink formed in the second area A2 from affecting the outermost sub-pixels SP1, SP2, and SP3 of the first area A1.

According to one or more embodiments, a black matrix 302, a color filter 320, an overcoat layer 520, the barrier wall 610 having the shape of an inverse taper, a color control member 340, and the thin film encapsulation layer 510 may be sequentially formed on the first area A1 of the front substrate 410.

According to one or more embodiments, the black matrix 302, the color filter 320, the overcoat layer 520, the barrier wall 610 having the shape of an inverse taper, the color control member 340, an organic resin layer (e.g., the organic resin layer 540 of FIGS. 4, 5, 6, 7, and 8,and the organic resin layer 940 of FIG. 9D), and the thin film encapsulation layer 510 may be sequentially formed on the first area A1 of the front substrate 410. The organic resin layer (e.g., the organic resin layer 540 of FIGS. 4, 5, 6, 7, and 8,and the organic resin layer 940 of FIG. 9D) may be formed to cover a corner portion (e.g., the corner portion CP of FIGS. 4, 5, and 6, between the barrier wall 610 surrounding the outermost sub-pixel SP of the first area A1 and the overcoat layer 520.

According to one or more embodiments, the thin film encapsulation layer 510 may be formed on an inclined corner surface 601 of the front substrate 410 and an inclined side surface 521 of the overcoat layer 520.

Since the thin film encapsulation layer 510 is formed to be gentle in the area corresponding to the corner portion, the corner surface 601 of the front substrate 410, and the inclined side surface 521 of the overcoat layer 520, the thin film encapsulation layer 510 may be formed to have a uniform thickness without disconnection in the entire area. The step coverage of the thin film encapsulation layer 510 may be improved, and thus moisture penetration into the thin film encapsulation layer 510 may be prevented.

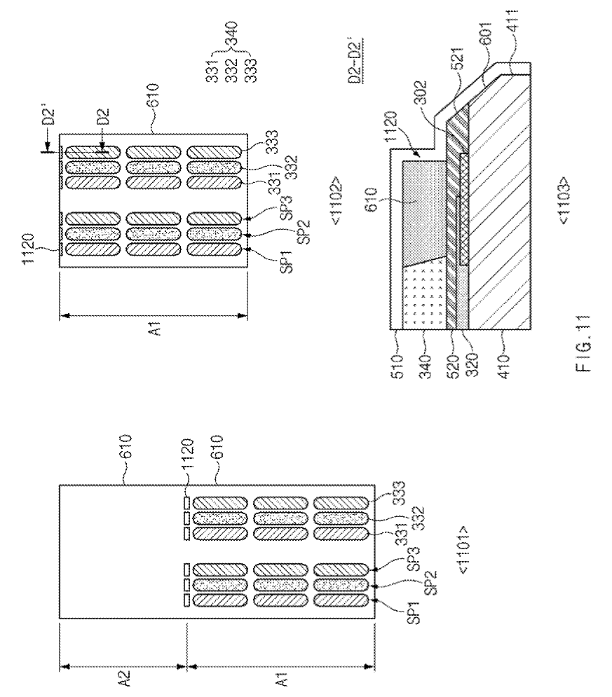

FIG. 11 is a view illustrating a method of manufacturing a color conversion panel according to one or more embodiments. In FIG. 11, drawing 1101 is a plan view illustrating the color conversion panel before a second area A2 is removed, drawing 1102 is a plan view illustrating the color conversion panel after the second area A2 is removed, and drawing 1103 is a sectional view of the color conversion panel taken along line D2-D2’ in drawing 1102.

The description of at least some components of the color conversion panel of FIG. 10 may be applied to at least some components of the color conversion panel of FIG. 11. For example, the description of the black matrix 302, the color filter 320, the overcoat layer 520, the barrier wall 610, the color control member 340, and the thin film encapsulation layer 510 of FIG. 10 may be applied to a black matrix 302, a color filter 320, an overcoat layer 520, a barrier wall 610, a color control member 340, and a thin film encapsulation layer 510 of FIG. 11.

Referring to FIG. 11, a front substrate 410 may include a first area A1 and the second area A2. The first area A1 may be an area where sub-pixels SP1, SP2, and SP3 are disposed. The second area A2 may be an outer area disposed outside the first area A1. In the second area A2, the barrier wall 610 may be disposed without the separate sub-pixels SP1, SP2, and SP3. The second area A2 may be an area capable of being removed after the thin film encapsulation layer 510 is formed in the first area A1.

A plurality of trenches 1120 may be formed between the first area A1 and the second area A2. The plurality of trenches 1120 may be arranged in a row in the width direction of each of the sub-pixels SP1, SP2, and SP3. The plurality of trenches 1120 may correspond to the plurality of sub-pixels SP1, SP2, and SP3 in a one-to-one manner. One of the plurality of trenches 1120 may be formed in the width direction of a first color conversion layer 331 of the first sub-pixel SP1. One of the plurality of trenches 1120 may be formed in the width direction of a second color conversion layer 332 of the second sub-pixel SP2. One of the plurality of trenches 1120 may be formed in the width direction of a transparent layer 333 of the third sub-pixel SP3. Each of the plurality of trenches 1120 may be formed between the barrier wall 610 formed in the first area A1 and the barrier wall 610 formed in the second area A2.

An ink for forming each of the first color conversion layer 331, the second color conversion layer 332, and the transparent layer 333 may be formed not only in the first area A1 but also in the second area A2. Since a residual ink formed in the second area A2 is trapped in the trenches 1120, the residual ink formed in the second area A2 may not flow into the outermost sub-pixels SP1, SP2, and SP3 of the first area A1 due to the trenches 1120.

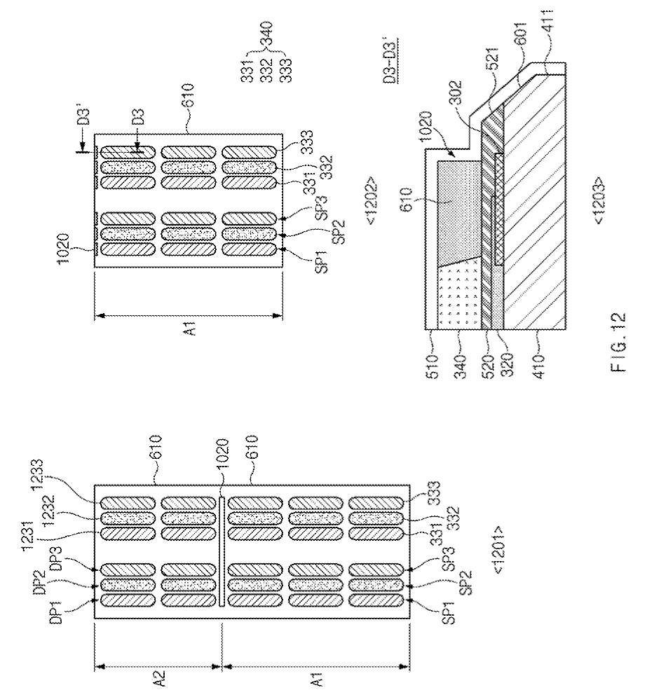

FIG. 12 is a view illustrating a method of manufacturing a color conversion panel according to one or more embodiments. In FIG. 12, drawing 1201 is a plan view illustrating the color conversion panel before a second area A2 is removed, drawing 1202 is a plan view illustrating the color conversion panel after the second area A2 is removed, and drawing 1203 is a sectional view of the color conversion panel taken along line D3-D3’ in drawing 1202.

The description of at least some components of the color conversion panel of FIG. 10 may be applied to at least some components of the color conversion panel of FIG. 12. For example, the description of the black matrix 302, the color filter 320, the overcoat layer 520, the barrier wall 610, the color control member 340, the thin film encapsulation layer 510, and the trench 1020 of FIG. 10 may be applied to a black matrix 302, a color filter 320, an overcoat layer 520, a barrier wall 610, a color control member 340, a thin film encapsulation layer 510, and a trench 1020 of FIG. 12.

Referring to FIG. 12, a front substrate 410 may include a first area A1 and the second area A2. The first area A1 may be an area where sub-pixels SP1, SP2, and SP3 are disposed. A first color conversion layer 331 of the first sub-pixels SP1, a second color conversion layer 332 of the second sub-pixels SP2, and a transparent layer 333 of the third sub-pixels SP3 may be separated by the barrier wall 610.

The second area A2 may be an outer area disposed outside the first area A1. The second area A2 may be an area where dummy sub-pixels DP1, DP2, and DP3 are disposed. A first dummy color conversion layer 1231 of the first dummy sub-pixels DP1, a second dummy color conversion layer 1232 of the second dummy sub-pixels DP2, and a third dummy transparent layer 1233 of the third dummy sub-pixels DP3 may be separated by the barrier wall 610. The first dummy color conversion layer 1231 may include an ink of the same material as the first color conversion layer 331. The first dummy color conversion layer 1231 may be formed simultaneously (or, together) with the first color conversion layer 331 through a single application process. The second dummy color conversion layer 1232 may include an ink of the same material as the second color conversion layer 332. The second dummy color conversion layer 1232 may be formed simultaneously (or, together) with the second color conversion layer 332 through a single application process. The dummy transparent layer 1233 may include an ink of the same material as the transparent layer 333. The dummy transparent layer 1233 may be formed simultaneously (or, together) with the transparent layer 333 through a single application process.

According to one or more embodiments, a first ink for forming the first color conversion layer 331 and the first dummy color conversion layer 1231 and a second ink for forming the second color conversion layer 332 and the second dummy color conversion layer 1232 may each be applied from the second area A2 to the first area A1. Since at least one of the first ink or the second ink is first applied to the second area A2, the unevenness of the ink application amount of the outermost sub-pixel SP formed in the first area A1 may be improved.

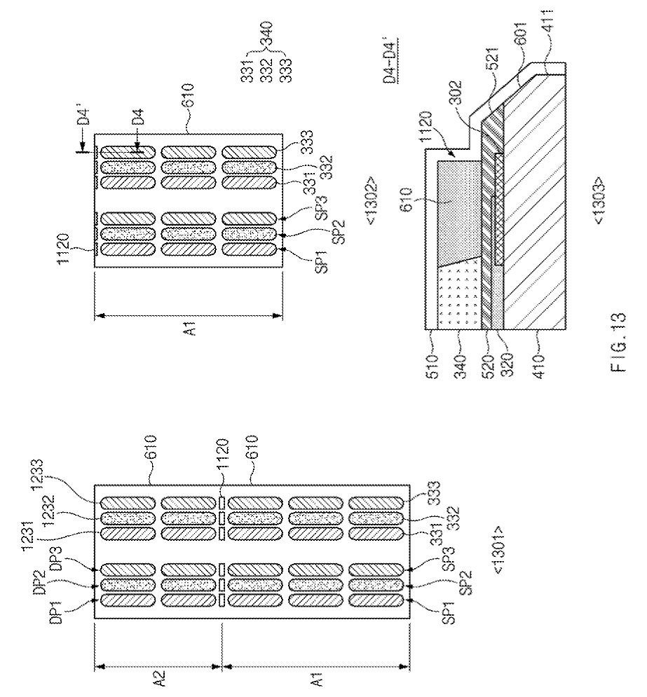

FIG. 13 is a view illustrating a method of manufacturing a color conversion panel according to one or more embodiments. In FIG. 13, drawing 1301 is a plan view illustrating the color conversion panel before a second area A2 is removed, drawing 302 is a plan view illustrating the color conversion panel after the second area A2 is removed, and drawing 1303 is a sectional view of the color conversion panel taken along line D4-D4’ in drawing 1302.

The description of at least some components of the color conversion panel of FIG. 11 may be applied to at least some components of the color conversion panel of FIG. 13. For example, the description of the black matrix 302, the color filter 320, the overcoat layer 520, the barrier wall 610, the color control member 340, the thin film encapsulation layer 510, and the plurality of trenches 1120 of FIG. 11 may be applied to a black matrix 302, a color filter 320, an overcoat layer 520, a barrier wall 610, a color control member 340, a thin film encapsulation layer 510, and a plurality of trenches 1120 of FIG. 13.

Referring to FIG. 13, a front substrate 410 may include a first area A1 and the second area A2. The first area A1 may be an area where sub-pixels SP1, SP2, and SP3 are disposed. A first color conversion layer 331 of the first sub-pixels SP1, a second color conversion layer 332 of the second sub-pixels SP2, and a transparent layer 333 of the third sub-pixels SP3 may be separated by the barrier wall 610.

The second area A2 may be an outer area disposed outside the first area A1. The second area A2 may be an area where dummy sub-pixels DP1, DP2, and DP3 are disposed. A first dummy color conversion layer 1231 of the first dummy sub-pixels DP1, a second dummy color conversion layer 1232 of the second dummy sub-pixels DP2, and a third dummy transparent layer 1233 of the third dummy sub-pixels DP3 may be separated by the barrier wall 610.

According to one or more embodiments, one of the plurality of trenches 1120 may be formed in the width direction of the first color conversion layer 331 of the first sub-pixel SP1. One of the plurality of trenches 1120 may be formed in the width direction of the second color conversion layer 332 of the second sub-pixel SP2. One of the plurality of trenches 1120 may be formed in the width direction of the transparent layer 333 of the third sub-pixel SP3. Each of the plurality of trenches 1120 may be formed between the barrier wall 610 formed in the first area A1 and the barrier wall 610 formed in the second area A2.

At least one of the plurality of trenches 1120 may be disposed between the barrier wall 610 surrounding the first color conversion layer 331 of the outermost first sub-pixel SP1 of the first area A1 and the barrier wall 610 surrounding the first dummy color conversion layer 1231 of the second area A2. At least one of the plurality of trenches 1120 may be disposed between the barrier wall 610 surrounding the second color conversion layer 332 of the outermost second sub-pixel SP2 of the first area A1 and the barrier wall 610 surrounding the second dummy color conversion layer 1232 of the second area A2. At least one of the plurality of trenches 1120 may be disposed between the barrier wall 610 surrounding the transparent layer 333 of the outermost third sub-pixel SP3 of the first area A1 and the barrier wall 610 surrounding the dummy transparent layer 1233 of the second area A2.

According to one or more embodiments, the first dummy color conversion layer 1231 may include a first ink of the same material as the first color conversion layer 331. The first dummy color conversion layer 1231 may be formed simultaneously (or, together) with the first color conversion layer 331 through a single application process. The second dummy color conversion layer 1232 may include a second ink of the same material as the second color conversion layer 332. The second dummy color conversion layer 1232 may be formed simultaneously (or, together) with the second color conversion layer 332 through a single application process.

According to one or more embodiments, the first ink for forming the first color conversion layer 331 and the first dummy color conversion layer 1231 and the second ink for forming the second color conversion layer 332 and the second dummy color conversion layer 1232 may each be applied from the second area A2 to the first area A1. Since at least one of the first ink or the second ink is first applied to the second area A2, the unevenness of the ink application amount of the outermost sub-pixel SP formed in the first area A1 may be improved.

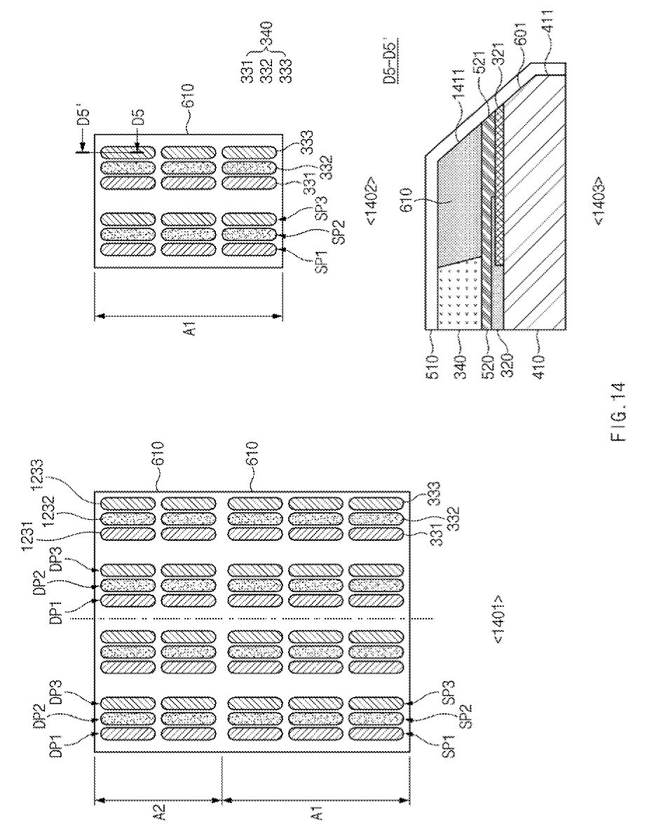

FIG. 14 is a view illustrating a method of manufacturing a color conversion panel according to one or more embodiments. In FIG. 14, drawing 1401 is a plan view illustrating the color conversion panel before a second area A2 is removed, drawing 1402 is a plan view illustrating the color conversion panel after the second area A2 is removed, and drawing 1403 is a sectional view of the color conversion panel taken along line D4-D4’ in drawing 1402.

The description of at least some components of the color conversion panel of FIG. 12 may be applied to at least some components of the color conversion panel of FIG. 14. For example, the description of the black matrix 302, the color filter 320, the overcoat layer 520, the barrier wall 610, the color control member 340, and the thin film encapsulation layer 510 of FIG. 12 may be applied to a black matrix 302, a color filter 320, an overcoat layer 520, a barrier wall 610, a color control member 340, and a thin film encapsulation layer 510 of FIG. 14.

Referring to FIG. 14, a front substrate 410 may include a first area A1 and the second area A2. The first area A1 may be an area where sub-pixels SP1, SP2, and SP3 are disposed. A first color conversion layer 331 of the first sub-pixels SP1, a second color conversion layer 332 of the second sub-pixels SP2, and a transparent layer 333 of the third sub-pixels SP3 may be separated by the barrier wall 610.

The second area A2 may be an outer area disposed outside the first area A1. The second area A2 may be an area where dummy sub-pixels DP1, DP2, and DP3 are disposed. A first dummy color conversion layer 1231 of the first dummy sub-pixels DP1, a second dummy color conversion layer 1232 of the second dummy sub-pixels DP2, and a third dummy transparent layer 1233 of the third dummy sub-pixels DP3 may be separated by the barrier wall 610.

According to one or more embodiments, before the second area A2 is removed from the first area A1, the barrier wall 610 may be disposed between the first area A1 and the second area A2. The barrier wall 610 may be disposed between the first color conversion layer 331 of the outermost first sub-pixel SP1 of the first area A1 and the first dummy color conversion layer 1231 of the second area A2. The barrier wall 610 may be disposed between the second color conversion layer 332 of the outermost second sub-pixel SP2 of the first area A1 and the second dummy color conversion layer 1232 of the second area A2. The barrier wall 610 may be disposed between the transparent layer 333 of the outermost third sub-pixel SP3 of the first area A1 and the dummy transparent layer 1233 of the second area A2.

According to one or more embodiments, after the second area A2 is removed from the first area A1, a side surface 1411 of the barrier wall 610 may be formed to be inclined. The thin film encapsulation layer 510 may be formed on an inclined corner surface 601 of the front substrate 410, an inclined side surface 521 of the overcoat layer 520, and the inclined side surface 1411 of the barrier wall 610.

The thin film encapsulation layer 510 may be formed to be gentle in the area corresponding to the corner surface 601 of the front substrate 410, the inclined side surface 521 of the overcoat layer 520, and the inclined side surface 1411 of the barrier wall 610. The thin film encapsulation layer 510 may be formed to have a uniform thickness without disconnection in the entire area. The step coverage of the thin film encapsulation layer 510 may be improved, and thus moisture penetration into the thin film encapsulation layer 510 may be prevented.

According to one or more embodiments, the second area A2 is not limited to the embodiment described in each drawing, and the second areas A2 described with reference to FIGS. 10, 11, 12, 13, and 14, may be applied in combination with each other. For example, a color conversion panel according to one or more embodiments may complexly employ the structure including the trench described with reference to FIGS. 10 and 12, the structure including the plurality of trenches described with reference to FIGS. 11 and 13, and the structure not including the trench described with reference to FIG. 14. In addition, the numbers and shapes of the trenches described with reference to FIGS. 10, 11, 12, and 13, are not limited to the examples described above and may be changed in various ways.

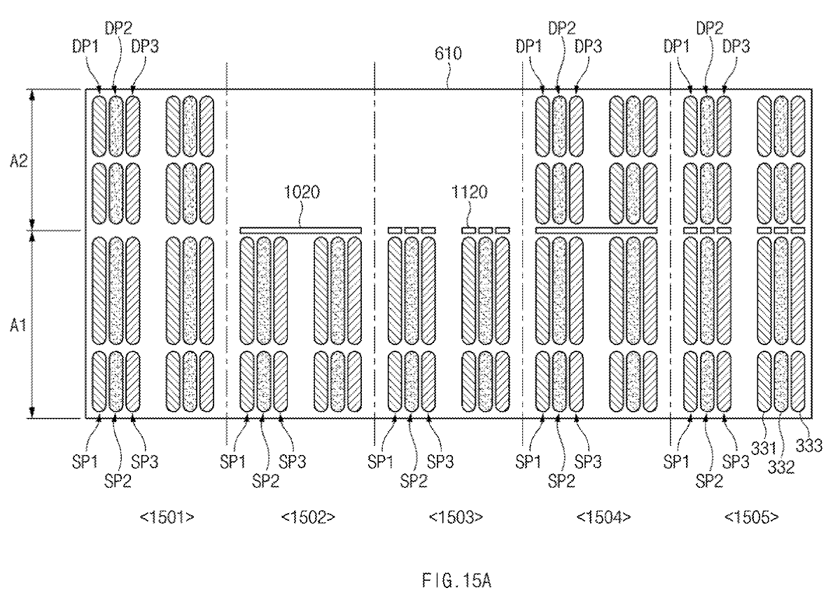

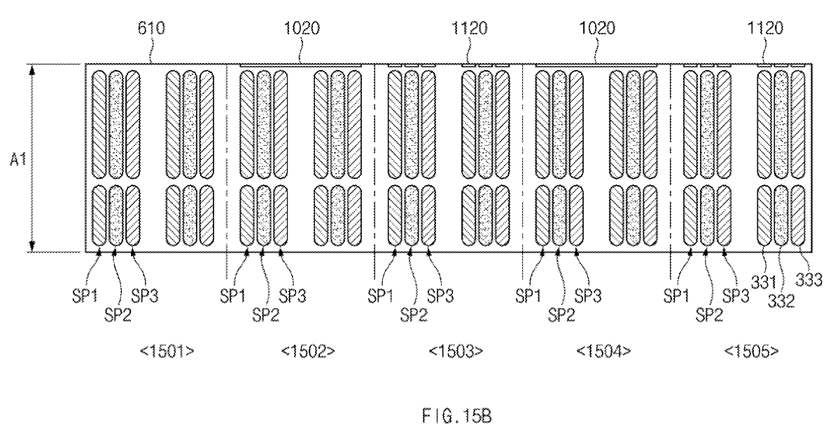

FIG. 15A is a plan view illustrating a color conversion panel according to one or more embodiments before a second area is removed, and FIG. 15B is a plan view illustrating the color conversion panel after the second area is removed. In FIGS. 15A and 15B, drawing 1501 is a view illustrating the color conversion panel having a structure that does not include a trench, drawing 1502 is a view illustrating the color conversion panel having a structure that includes one trench, drawing 1503 is a view illustrating the color conversion panel having a structure that includes a plurality of trenches, drawing 1504 is a view illustrating the color conversion panel having a structure that includes one trench and a plurality of dummy sub-pixels, and drawing 1505 is a view illustrating the color conversion panel having a structure that includes a plurality of trenches and a plurality of dummy sub-pixels.

The description of at least some components of at least one of the color conversion panels of FIGS. 10 to 14 may be applied to at least some components of the color conversion panel of FIGS. 15A and 15B. For example, the description of the trench 1020 of FIGS. 10 and 12 may be applied to one trench 1020 of FIGS. 15A and 15B, the description of the plurality of trenches 1120 of FIGS. 11 and 13 may be applied to a plurality of trenches 1120 of FIGS. 15A and 15B, and the description of the dummy sub-pixels DP1, DP2, and DP3 of FIGS. 12, 13, and 14 may be applied to dummy sub-pixels DP1, DP2, and DP3 of FIGS. 15A and 15B.

Referring to FIGS. 15A and 15B, a front substrate 410 may include a first area A1 and the second area A2. The first area A1 may be an area where sub-pixels SP1, SP2, and SP3 are disposed. A first color conversion layer 331 of the first sub-pixels SP1, a second color conversion layer 332 of the second sub-pixels SP2, and a transparent layer 333 of the third sub-pixels SP3 may be separated by the barrier wall 610.

At least one of the first color conversion layer 331, the second color conversion layer 332, and the transparent layer 333 disposed in the outermost area of the first area A1 may be formed long. At least one of the first color conversion layer 331, the second color conversion layer 332, or the transparent layer 333 disposed in the outermost area of the first area A1 adjacent to the second area A2 may be formed long. At least one of the first color conversion layer 331, the second color conversion layer 332, or the transparent layer 333 disposed in the outermost area of the first area A1 may be formed longer than at least one of the first color conversion layer 331, the second color conversion layer 332, or the transparent layer 333 disposed in the remaining area other than the outermost area.

The first color conversion layer 331 of the outermost first sub-pixel SP1 of the first area A1 and the first color conversion layer 331 of the first sub-pixel SP1 adjacent to the outermost first sub-pixel SP1 may be integrated with each other and may be formed long. The second color conversion layer 332 of the outermost second sub-pixel SP2 of the first area A1 and the second color conversion layer 332 of the second sub-pixel SP2 adjacent to the outermost second sub-pixel SP2 may be integrated with each other and may be formed long. The transparent layer 333 of the outermost third sub-pixel SP3 of the first area A1 and the transparent layer 333 of the third sub-pixel SP3 adjacent to the outermost third sub-pixel SP3 may be integrated with each other and may be formed long. By adjusting the ink application amount of the sub-pixels SP in the outermost area of the first area A1 to an average value, the unevenness of the ink application amount of the outermost sub-pixels SP formed in the first area A1 may be improved.

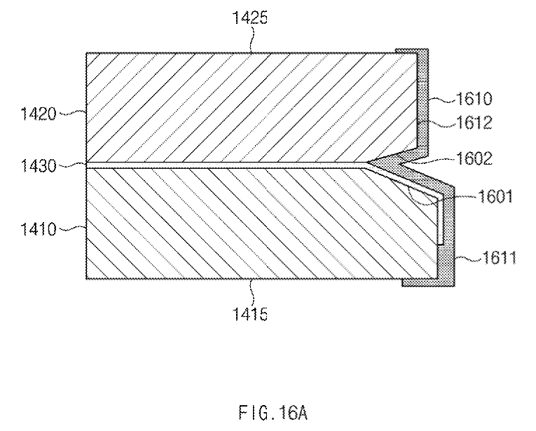

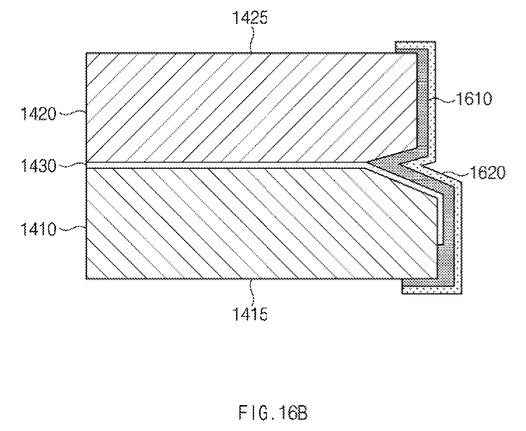

FIGS. 16A and 16B are sectional views illustrating a method of manufacturing a display including a color conversion panel according to one or more embodiments. In FIGS. 16A and 16B, the color conversion panel and the light source panel described above will be described as an example.

Referring to FIG. 16A, a light source panel 1420 (e.g., the light source panel 310 of FIG. 2) and a color conversion panel 1410 (e.g., the color conversion panel 300 of FIG. 2) may be provided. The color conversion panel 1410 may protrude further than the light source panel 1420 to prevent a seam phenomenon in which the light source panel 1420 is exposed to a user’s eyes.

The color conversion panel 1410 may include a first side area 1611 and a first inclined area 1601. The first side area 1611 may form an obtuse angle with the first inclined area 1601. The first inclined area 1601 may be an area corresponding to an organic resin layer (e.g., the organic resin layer 540 of FIG. 6) disposed on a side surface of a barrier wall (e.g., the barrier wall 610 FIG. 6) having the shape of an inverse taper.

The light source panel 1420 may include a second side area 1612 and a second inclined area 1602. The second side area 1612 may form an obtuse angle with the second inclined area 1602. The second inclined area 1602 may be formed to face a portion of the first inclined area 1601.

The light source panel 1420 and the color conversion panel 1410 may be bonded to each other through a bonding agent 1430 such that the first inclined area 1601 and the second inclined area 1602 face each other. The bonding agent 1430 may include, for example, an optically clear adhesive (OCA) or/and an optically clear resin (OCR).

A side encapsulation layer 1610 may be formed after the light source panel 1420 and the color conversion panel 1410 are bonded to each other. The side encapsulation layer 1610 may be formed to cover at least one of a portion of a front area 1415 of the color conversion panel 1410, the first side area 1611, the first inclined area 1601, a portion of a rear area 1425 of the light source panel 1420, the second side area 1612, or the second inclined area 1602. The side encapsulation layer 1610 may be formed to cover a portion of the front area 1415 of the color conversion panel 1410, the first side area 1611, the first inclined area 1601, a portion of the rear area 1425 of the light source panel 1420, the second side area 1612, and the second inclined area 1602. The side encapsulation layer 1610 may be formed in at least one layer structure including at least one of Al₂O₃, SiNx, SiOx, or SiON. The side encapsulation layer 1610 may block moisture and/or oxygen from penetrating through the side surfaces of the light source panel 1420 and the color conversion panel 1410 bonded to each other.

After the side encapsulation layer 1610 is formed, a side protection member (or, a side seal) 1620 may be formed as illustrated in FIG. 16B. The side protection member 1620 may be formed to cover the side encapsulation layer 1610.

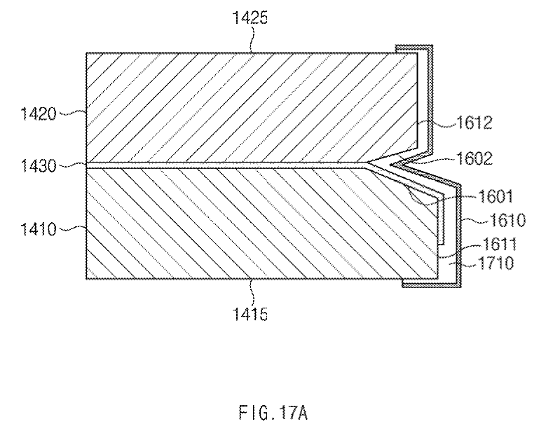

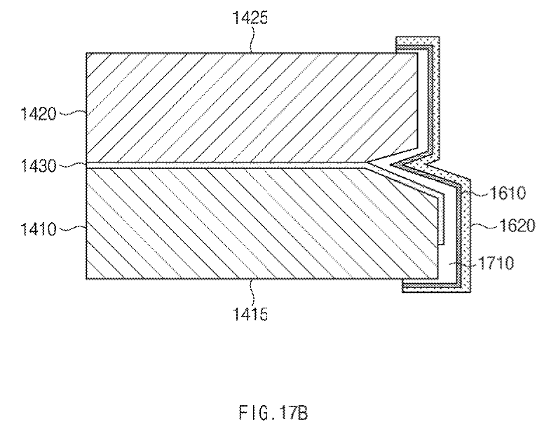

FIGS. 17A and 17B are sectional views illustrating a method of manufacturing a display including a color conversion panel according to one or more embodiments. In FIGS. 17A and 17B, the color conversion panel and the light source panel described above will be described as an example. The description of at least some components of the display of FIGS. 16A and 16B may be applied to at least some components of the display of FIGS. 17A and 17B. For example, the description of the light source panel 1420, the color conversion panel 1410, the side encapsulation layer 1610, and the side protection member 1620 of FIGS. 16A and 16B may be applied to a light source panel 1420, a color conversion panel 1410, a side encapsulation layer 1610, and a side protection member 1620 of FIGS. 17A and 17B.

Referring to FIG. 17A, the light source panel 1420 (e.g., the light source panel 310 of FIG. 2) and the color conversion panel 1410 (e.g., the color conversion panel 300 of FIG. 2) may be provided. The light source panel 1420 and the color conversion panel 1410 may be bonded to each other through a bonding agent 1430 such that a second inclined area 1602 of the light source panel 1420 and a first inclined area 1601 of the color conversion panel 1410 face each other. The bonding agent 1430 may include, for example, an optically clear adhesive (OCA) or/and an optically clear resin (OCR).

A side planarization layer 1710 may be formed after the light source panel 1420 and the color conversion panel 1410 are bonded to each other. The side planarization layer 1710 may include an organic insulating material. The side planarization layer 1710 may flatten a step between the light source panel 1420 and the color conversion panel 1410. The side planarization layer 1710 may be formed to fill at least a portion of the space between the second inclined area 1602 of the light source panel 1420 and the first inclined area 1601 of the color conversion panel 1410. For example, the side planarization layer 1710 may include the same material as the side protection member 1620.

Referring to FIG. 17B, the side encapsulation layer 1610 may be formed on the side planarization layer 1710 to overlap the side planarization layer 1710. The side encapsulation layer 1610 may be formed to cover the side planarization layer 1710 on at least one of a portion of a front area 1415 of the color conversion panel 1410, a first side area 1611, the first inclined area 1601, a portion of a rear area 1425 of the light source panel 1420, a second side area 1612, or the second inclined area 1602. The side encapsulation layer 1610 may be formed to cover the side planarization layer 1710 on a portion of the front area 1415 of the color conversion panel 1410, the first side area 1611, the first inclined area 1601, a portion of the rear area 1425 of the light source panel 1420, the second side area 1612, and the second inclined area 1602. The side encapsulation layer 1610 may be formed in at least one layer structure including at least one of Al₂O₃, SiNx, SiOx, or SiON. The side encapsulation layer 1610 may block moisture and/or oxygen from penetrating through the side surfaces of the light source panel 1420 and the color conversion panel 1410 bonded to each other.

After the side encapsulation layer 1610 is formed, the side protection member (or, the side seal) 1620 may be formed. The side protection member 1620 may be formed to cover the side encapsulation layer 1610.

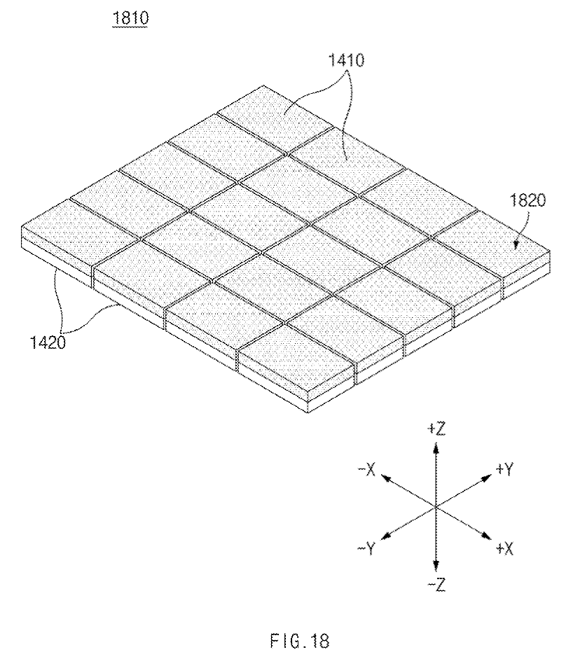

FIG. 18 is a view illustrating a display according to one or more embodiments. In FIG. 18, the color conversion panel and the light source panel described above will be described as an example. The description of at least some components of the displays of FIGS. 16B and 17B may be applied to at least some components of the display of FIG. 18. For example, the description of the light source panel 1420 and the color conversion panel 1410 of FIGS. 16B and 17B may be applied to light source panels 1420 and color conversion panels 1410 of FIG. 18.

Referring to FIG. 18, the display 1810 according to one or more embodiments may include the plurality of light source panels 1420 and the plurality of color conversion panels 1410. The plurality of light source panels 1420 and the plurality of color conversion panels 1410 may be provided in equal numbers.

The display 1810 may be manufactured to have a large area by tiling a plurality of unit modules 1820 in which the plurality of color conversion panels 1410 are bonded to the plurality of light source panels 1420, respectively, through a bonding agent. The gap between the plurality of unit modules 1820 may be formed to be narrow such that no seam is visible. For example, the gap between the plurality of unit modules 1820 may be 50 μm or less.

One or more embodiments of the disclosure may provide a display of a large-area electronic device that is capable of supporting moisture penetration prevention performance.

Furthermore, one or more embodiments of the disclosure may provide a modular display capable of implementing a narrow bezel while improving the performance of preventing moisture penetration through a side surface of a color conversion panel.

In addition, one or more embodiments of the disclosure may provide a display including a color conversion panel capable of reducing non-uniformity in printing quality of a color conversion layer of the outermost sub-pixels. The displays according to the various embodiments disclosed in the disclosure are applicable to any device having a display function without limitation. The displays may be applied to wired electronic devices, wireless electronic devices, fixed electronic devices, mobile (or, portable) electronic devices, small electronic devices, medium-sized electronic devices, and/or large electronic devices. For example, the electronic devices may include a TV, a portable communication device (e.g., a smartphone), a computer device, a multimedia device, a medical device, a camera, a wearable device, or a home appliance.

A display including a plurality of sub-pixels according to one or more embodiments of the disclosure may include a light source panel 310 or 1420 and a color conversion panel 300 or 1410 that faces the light source panel.

According to one or more embodiments, the color conversion panel 300, 500, or 1410 may include a front substrate 301 or 410, a color conversion member 330 disposed on the front substrate, a barrier wall 304 or 610 disposed on the front substrate, an organic resin layer 540 formed to cover a side surface of the barrier wall 610 that separates the plurality of sub-pixels disposed at the outermost position of the front substrate, the organic resin layer 540 being disposed between the side surface of the barrier wall 610 and a side surface of the front substrate, and a thin film encapsulation layer 510 disposed on the organic resin layer.

According to one or more embodiments, the barrier wall may have a gradually increasing width toward the light source panel 310 or 1420.

According to one or more embodiments, the organic resin layer 540 may have a gradually decreasing width toward the light source panel 310 or 1420.

According to one or more embodiments, the barrier wall 610 may include an inclined side surface having a shape of an inverse taper, and the organic resin layer 540 may include an inclined surface having a shape of a positive taper.

According to one or more embodiments, the front substrate 410 may include a plurality of side surfaces 411, 412, 413, and 414 and a first surface 416 disposed to be bent from the plurality of side surfaces.

According to one or more embodiments, the barrier wall 610 may include an inclined side surface 613 that forms an obtuse angle with the first surface 416.

According to one or more embodiments, the organic resin layer 540 may include an inclined surface 541 that forms an acute angle with the first surface 416.

According to one or more embodiments, the front substrate 410 may further include a corner surface 601 disposed between at least one of the plurality of side surfaces and the first surface 416 and formed in an inclined or round shape.

According to one or more embodiments, the thin film encapsulation layer may include a first thin film encapsulation layer 710 formed along the corner surface 601 of the front substrate 410 and a second thin film encapsulation layer 720 formed along a side surface of the organic resin layer 540.

According to one or more embodiments, the organic resin layer 540 may be disposed between the first thin film encapsulation layer 710 and the second thin film encapsulation layer 720.

According to one or more embodiments, the display may further include an overcoat layer 520 disposed on the front substrate 410, and a side surface of the overcoat layer 520 may overlap the organic resin layer 540 and may protrude further toward the side surface of the front substrate 410 than the barrier wall 610.

According to one or more embodiments, the organic resin layer 540 may include the same material as the overcoat layer 520 or may include a liquid-repellent material.

According to one or more embodiments, the display may further include at least one trench 1020 or 1120 disposed between the barrier wall 610 that separates the plurality of sub-pixels located at the outermost position of the front substrate 410 and the side surface of the front substrate 410.

According to one or more embodiments, the at least one trench 1020 or 1120 may be formed along the plurality of sub-pixels to correspond to the plurality of sub-pixels in a one-to-many manner or may be formed in plural numbers to correspond to the plurality of sub-pixels in a one-to-one manner.

According to one or more embodiments, the display may further include a side encapsulation layer 1610 formed to cover a side surface of the light source panel 1420 and a side surface of the color conversion panel 1410.

According to one or more embodiments, the display may further include a side planarization layer 1710 disposed between each of the side surface of the light source panel 1420 or the side surface of the color conversion panel 1410 and the side encapsulation layer.

According to one or more embodiments, the display may further include a side protection member 1620 formed to cover the side encapsulation layer 1610.

According to one or more embodiments, at least one of the thin film encapsulation layer 510 or the side encapsulation layer 1610 may be formed in at least one layer structure including at least one of Al₂O₃, SiNx, SiOx, or SiON.

A color conversion panel according to one or more embodiments of the disclosure may include a front substrate 410, color conversion layers 330 disposed on the front substrate, a barrier wall 610 disposed between the color conversion layers on the front substrate and formed to separate a plurality of sub-pixels, an organic resin layer 540 formed to cover a side surface of the barrier wall that separates the plurality of sub-pixels disposed at the outermost position of the front substrate, the organic resin layer being disposed between the side surface of the barrier wall and a side surface of the front substrate, and a thin film encapsulation layer 510 disposed on the organic resin layer 540.

According to one or more embodiments, the barrier wall 610 may have a gradually increasing width farther away from the front substrate 410.

According to one or more embodiments, the organic resin layer 540 may have a gradually increasing width toward the front substrate 410.

According to one or more embodiments, the front substrate 410 may include a plurality of side surfaces 411, 412, 413, and 414, a first surface 416 disposed to be bent from the plurality of side surfaces, and a corner surface 601 disposed between at least one of the plurality of side surfaces 411, 412, 413, and 414 and the first surface 416 and formed in an inclined or round shape

According to one or more embodiments, the thin film encapsulation layer 510 may include a first thin film encapsulation layer 710 formed along the corner surface 601 of the front substrate 410 and a second thin film encapsulation layer 720 formed along a side surface of the organic resin layer 540, and the organic resin layer 540 may be disposed between the first thin film encapsulation layer 710 and the second thin film encapsulation layer 720.

According to one or more embodiments, the color conversion panel may further include an overcoat layer 520 disposed on the front substrate 410, and a side surface of the overcoat layer 520 may overlap the organic resin layer 540 and may protrude further toward the side surface of the front substrate 410 than the side surface of the barrier wall 610.

A display according to one or more embodiments of the disclosure may include a color conversion panel, and the color conversion panel 300, 500, or 1410 may include a front substrate 301 or 410, a color conversion layer 330 disposed on the front substrate, a barrier wall 304 or 610 that is disposed on the front substrate and that separates a plurality of sub-pixels, an organic resin layer 540 that has a shape of a positive taper and that is formed to cover a side surface of the barrier wall 610 that separates the plurality of sub-pixels disposed at the outermost position of the front substrate, and a thin film encapsulation layer 510 disposed on the organic resin layer.

According to one or more embodiments, the barrier wall 304 or 610 may be formed in a shape of an inverse taper.

It should be appreciated that embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. For example, the expression, "at least one of A, B, or C," should be understood as including only A, only B, only C, both A and B, both A and C, both B and C, or all of A, B, and C. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element. According to the situation, the expression “adapted to or configured to” used in this disclosure may be used interchangeably with, for example, the expression “suitable for”, “having the capacity to”, “adapted to”, “made to”, “capable of”, or “designed to” in hardware or software. The expression “a device configured to” may mean that the device is “capable of” operating together with another device or other components. For example, a “processor set to (or configured to) perform A, B, and C” may mean a dedicated processor (e.g., an embedded processor) for performing corresponding operations or a generic-purpose processor (e.g., a CPU or an AP) that performs corresponding operations by executing one or more programs stored in a memory device (e.g., a memory).

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. The “module” may be implemented mechanically or electronically and may include, for example, an application-specific integrated circuit (ASIC) chip, field-programmable gate arrays (FPGAs), or a programmable-logic device for performing some operations, which are known or will be developed.

At least a part of an apparatus (e.g., modules or functions thereof) or a method (e.g., operations) according to various embodiments may be implemented by instructions stored in computer-readable storage media (e.g., the memory 130) in the form of a program module. The instructions, when executed by a processor (e.g., the processor 120), may cause the processor to perform functions corresponding to the instructions. The computer-readable storage media may include a hard disk, a floppy disk, a magnetic media (e.g., a magnetic tape), an optical media (e.g., CD-ROM, DVD, magneto-optical media (e.g., a floptical disk)), an embedded memory, and the like. The instructions may include a code made by a compiler or a code executable by an interpreter.

According to embodiments, each component (e.g., a module or a program) of the above-described components may include a single entity or multiple entities, and some of the multiple entities may be separately disposed in different components. According to embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. A display comprising: a light source panel; and a color conversion panel facing the light source panel, wherein the color conversion panel comprises: a front substrate; a color conversion layer on the front substrate; a barrier wall on the front substrate and separating each of a plurality of sub-pixels of the display; an organic resin layer on a side surface of the barrier wall, wherein the organic resin layer separates the plurality of sub-pixels at an outermost position of the front substrate, and the organic resin layer is between a side surface of the barrier wall and a side surface of the front substrate; and a thin film encapsulation layer on the organic resin layer.

2. The display of claim 1, wherein the barrier wall has a first width at a first distance from the light source panel and a second width at a second distance from the light source panel, the first width is greater than the second width, and the first distance is less than the second distance, and
wherein the organic resin layer has a third width at a third distance from the light source panel and a fourth width at a fourth distance from the light source panel, the third width is less than the fourth width, and the third distance is less than the fourth distance.

3. The display of claim 1, wherein the barrier wall comprises an inclined side surface having a shape of an inverse taper, and
wherein the organic resin layer comprises an inclined surface having a shape of a positive taper.

4. The display of claim 1, wherein the front substrate comprises:
a plurality of side surfaces; and
a first surface bent from the plurality of side surfaces,
wherein the barrier wall comprises an inclined side surface having an obtuse angle with the first surface, and
wherein the organic resin layer comprises an inclined surface having an acute angle with the first surface.

5. The display of claim 4, wherein the front substrate further comprises a corner surface between at least one of the plurality of side surfaces and the first surface, and the corner surface having an inclined or round shape.

6. The display of claim 5, wherein the thin film encapsulation layer comprises:
a first thin film encapsulation layer on the corner surface of the front substrate; and
a second thin film encapsulation layer on a side surface of the organic resin layer, and
wherein the organic resin layer is between the first thin film encapsulation layer and the second thin film encapsulation layer.

7. The display of claim 1, further comprising:
an overcoat layer on the front substrate,
wherein a side surface of the overcoat layer overlaps the organic resin layer and protrudes further toward the side surface of the front substrate than the side surface of the barrier wall.

8. The display of claim 7, wherein the organic resin layer comprises a same material as the overcoat layer or a liquid-repellent material.

9. The display of claim 1, further comprising:
at least one trench between the barrier wall, the at least one trench separating the plurality of sub-pixels located at the outermost position of the front substrate and the side surface of the front substrate.

10. The display of claim 9, wherein the at least one trench corresponds to the plurality of sub-pixels in a one-to-many manner.

11. The display of claim 9, wherein the at least one trench corresponds to the plurality of sub-pixels in a one-to-one manner.

12. The display of claim 1, further comprising:
a side encapsulation layer on a side surface of the light source panel and a side surface of the color conversion panel.

13. The display of claim 12, further comprising:
a side planarization layer between at least one of the side surface of the light source panel or the side surface of the color conversion panel and the side encapsulation layer.

14. The display of claim 12, further comprising:
a side protection member on the side encapsulation layer.

15. The display of claim 14, wherein at least one of the thin film encapsulation layer or the side encapsulation layer comprises at least one layer structure comprising at least one of Al₂O₃ SiNx, SiOx, or SiON.

16. A color conversion panel comprising:
a front substrate;
color conversion layers on the front substrate;
a barrier wall between the color conversion layers on the front substrate;
an organic resin layer on a side surface of the barrier wall, wherein the organic resin layer separates a plurality of sub-pixels at an outermost position of the front substrate, and the organic resin layer is between a side surface of the barrier wall and a side surface of the front substrate; and
a thin film encapsulation layer on the organic resin layer.

17. The color conversion panel of claim 16, wherein the barrier wall has a first width at a first distance from the front substrate and a second width at a second distance from the front substrate, the first width is less than the second width, and the first distance is less than the second distance, and
wherein the organic resin layer has a third width at a third distance from the front substrate and a fourth width at a fourth distance from the front substrate, the third width is greater than the fourth width, and the third distance is less than the fourth distance.

18. The color conversion panel of claim 16, wherein the front substrate comprises:
a plurality of side surfaces;
a first surface bent from the plurality of side surfaces; and
a corner surface between at least one of the plurality of side surfaces and the first surface and having an inclined or round shape.

19. The color conversion panel of claim 18, wherein the thin film encapsulation layer comprises:
a first thin film encapsulation layer on the corner surface of the front substrate; and
a second thin film encapsulation layer on a side surface of the organic resin layer, and
wherein the organic resin layer is between the first thin film encapsulation layer and the second thin film encapsulation layer.

20. The color conversion panel of claim 16, further comprising:
an overcoat layer on the front substrate,
wherein a side surface of the overcoat layer overlaps the organic resin layer and protrudes further toward the side surface of the front substrate than the side surface of the barrier wall.
